(19) United States
(12) Patent Application Publication
(10) Pub. No.: US 2022/0293886 A1
(43) Pub. Date: Sep. 15, 2022

(54) DISPLAY DEVICE

(71) Applicant: Samsung Display Co., LTD., Yongin-si (KR)

(72) Inventors: Jong Baek SEON, Yongin-si (KR); Deok Hoi Kim, Seongnam-si (KR); Hun Kim, Seoul (KR)

(21) Appl. No.: 17/685,305

(22) Filed: Mar. 2, 2022

(30) Foreign Application Priority Data
Mar. 10, 2021 (KR) 10-2021-0031411

(51) Int. Cl. H01L 51/52

(52) U.S. Cl. CPC H01L 51/5253

(57) ABSTRACT

A display device includes: a first substrate; a second substrate disposed on the first substrate and including a plurality of voids; at least one inorganic layer disposed on the second substrate; at least one transistor disposed on the at least one inorganic layer; and a light-emitter disposed on the at least one transistor. The second substrate is in contact with the at least one inorganic layer and has a dielectric constant less than a dielectric constant of the at least one inorganic layer.

### CROSS REFERENCE TO RELATED APPLICATION

This application claims priority from and the benefit of Korean Patent Application No. 10-2021-0031411, filed on Mar. 10, 2021, which is hereby incorporated by reference for all purposes as if fully set forth herein.

### BACKGROUND

### Field

Embodiments of the invention relate generally to a display device, and more particularly, to a flexible display device including transistors disposed on a substrate.

### Discussion of the Background

As our information-oriented society evolves, various demands for display devices to display images are ever increasing. Display devices include liquid-crystal displays (LCDs), plasma display panels (PDPs), organic light-emitting displays (OLEDs), micro light-emitting diode displays, etc.

A display device includes light-emitting diodes and a plurality of thin-film transistors connected to the light-emitting diodes. The plurality of thin-film transistors may include a thin-film transistor including polycrystalline silicon or a thin-film transistor including oxide. A thin-film transistor containing polycrystalline silicon has an advantage in that it may supply driving current stably. A thin-film transistor containing oxide has advantages in that it may be turned on quickly and exhibits good off-current characteristics.

The above information disclosed in this Background section is only for understanding of the background of the inventive concepts, and, therefore, it may contain information that does not constitute prior art.

### SUMMARY

Applicant discovered that electrical characteristics of thin-film transistors may deteriorate or vary due to electron charging and interfacial polarization in a flexible substrate, which may cause undesirable afterimages on a screen.

Display devices constructed according to principles and illustrative implementations of the invention are capable of displaying images with improved display quality and reliability. For example, the display device may maintain electrical characteristics of thin-film transistors as desired and may reduce afterimages on a screen. The display device may include one or more sub-substrates in contact with a barrier layer, and the one or more sub-substrates may have reduced dielectric constants to prevent or at least reduce electron charging and interfacial polarization from occurring at or around the interface between the barrier layer and the one or more sub-substrates.

Additional features of the inventive concepts will be set forth in the description which follows, and in part will be apparent from the description, or may be learned by practice of the inventive concepts.

According to one aspect of the invention, a display device includes: a first substrate; a second substrate disposed on the first substrate and including a plurality of voids; at least one inorganic layer disposed on the second substrate; at least one transistor disposed on the at least one inorganic layer; and a light-emitter disposed on the at least one transistor. The second substrate is in contact with the at least one inorganic layer and has a dielectric constant less than a dielectric constant of the at least one inorganic layer.

The voids in the second substrate may include pores having a porosity in the range of about 10% to about 40%.

The second substrate may have a dielectric constant of about 2 to about 3, and the at least one inorganic layer may have a dielectric constant of about 3.5 or less.

The first substrate may include at least one non-porous base substrate, and the second substrate may include at least one porous sub-substrate including the plurality of voids.

The at least one inorganic layer may include a polymer resin or a silica-based material, and the silica-based material may include one selected from the group consisting of: porous silica, HSQ, OSG, and FSG; and the polymer resin includes one selected from the group consisting of: PTFE, BPDA-PDA, PAE, SiLK, BCB, Parylene-N, and Parylene-F.

The at least one inorganic layer may include a plurality of voids.

The at least one inorganic layer may include at least one of fluorine, boron, phosphorus, arsenic and argon.

The first substrate may include a first base substrate and a second base substrate disposed on the first base substrate, and the second substrate may be disposed on the second base substrate.

The display device may further include a third substrate disposed between the first base substrate and the second base substrate. The third substrate may include a plurality of voids.

Each of the first base substrate, the second base substrate, the second substrate and the third substrate may include a polyimide resin.

The at least one inorganic layer may include at least one barrier layer and at least one buffer layer disposed on the at least one barrier layer.

The second substrate may include a plurality of recesses formed on at least one surface.

The light-emitter may include an organic light-emitting diode.

According to another aspect of the invention, a display device includes: a plurality of base substrates; a first sub-substrate disposed on the plurality of base substrates and including a plurality of voids; at least one inorganic layer disposed on the base substrates; at least one transistor disposed on the at least one inorganic layer; and a light-emitting diode disposed on the at least one transistor. The first sub-substrate is in contact with the at least one inorganic layer and has a dielectric constant less than a dielectric constant of the at least one inorganic layer.

The voids in the first sub-substrate may include pores having a porosity ranging from about 10% to about 40%.

The first sub-substrate may have a dielectric constant of about 2 to about 3, and the at least one inorganic layer may have a dielectric constant of about 3.5 or less.

The at least one inorganic layer may include a polymer resin or a silica-based material, and the silica-based material may include one selected from the group consisting of: porous silica, HSQ, OSG and FSG; and the polymer resin includes one selected from the group consisting of: PTFE, BPDA-PDA, PAE, SiLK, BCB, Parylene-N, and Parylene-F.

The at least one inorganic layer may include a plurality of voids. The at least one inorganic layer may include at least one of fluorine, boron, phosphorus, arsenic and argon.

The plurality of base substrates may include a first base substrate and a second base substrate disposed on the first base substrate. The first sub-substrate may be disposed between the first base substrate and the second base substrate.

The display device may further include a second sub-substrate disposed on the second base substrate. The second sub-substrate may include a plurality of voids.

The light-emitter may include an organic light-emitting diode.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a perspective view of an embodiment of a display device.

FIG. 2 is a plan view of the display panel of FIG. 1.

FIG. 3 is a circuit diagram of an embodiment of a representative one of the sub-pixels of FIG. 2.

FIG. 4 is a cross-sectional view of an embodiment of a display device constructed according to the principles of the invention.

FIG. 5 is a Maxwell-Garnett graph showing the dielectric constant of a thin film according to its porosity.

FIG. 6 is a cross-sectional view of another embodiment of a display device constructed according to the principles of the invention.

FIG. 7 is a cross-sectional view of still another embodiment of a display device constructed according to the principles of the invention.

FIG. 8 is a cross-sectional view of yet another embodiment of a display device constructed according to the principles of the invention.

FIG. 9 is a cross-sectional view of another embodiment of a display device constructed according to the principles of the invention.

FIG. 10 is a cross-sectional view of yet another embodiment of a display device constructed according to the principles of the invention.

FIG. 11 is a cross-sectional view of still another embodiment of a display device constructed according to the principles of the invention.

FIG. 12 is a cross-sectional view of still yet another embodiment of a display device constructed according to the principles of the invention.

FIG. 13 is a cross-sectional view of another embodiment of a display device constructed according to the principles of the invention.

FIG. 14 is a cross-sectional view of yet another embodiment of a display device constructed according to the principles of the invention.

FIG. 15 is a cross-sectional view of still another embodiment of a display device constructed according to the principles of the invention.

FIG. 16 is a cross-sectional view of yet still another embodiment of a display device constructed according to the principles of the invention.

FIG. 17 is a cross-sectional view of another embodiment of a display device constructed according to the principles of the invention.

FIG. 18 is a cross-sectional view of still another embodiment of a display device constructed according to the principles of the invention.

FIG. 19 is a cross-sectional view of yet another embodiment of a display device constructed according to the principles of the invention.

FIG. 20 is a cross-sectional view of still yet another embodiment of a display device constructed according to the principles of the invention.

FIGS. 21 to 31 are cross-sectional views of other embodiments of display devices constructed according to the principles of the invention.

FIGS. 32 to 47 are cross-sectional views of still other embodiments of display devices constructed according to the principles of the invention.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

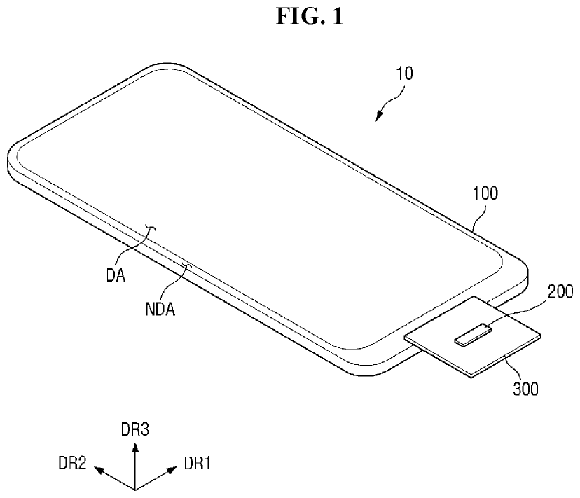

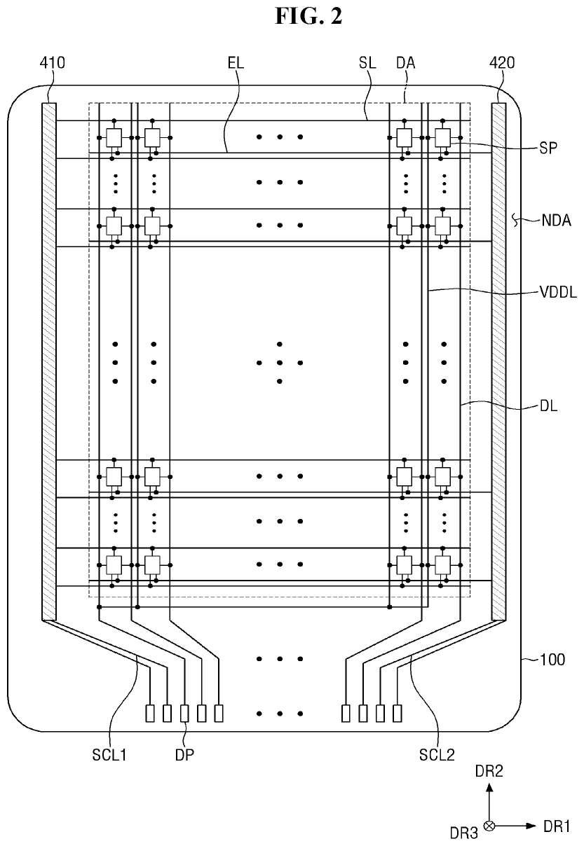

FIG. 1 is a perspective view of an embodiment of a display device. FIG. 2 is a plan view of the display panel of FIG. 1.

As used herein, the terms “above,” “top” and “upper surface” refer to the upper side of the display panel 100, i.e., the side indicated by the arrow in a third direction DR3, whereas the terms “below,” “bottom” and “lower surface” refer to the lower side of the display panel 100, i.e., the opposite side in the third direction DR3.

A display device 10 is designed for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and an ultra mobile PC (UMPC), as well as the display screen of various products such as a television, a notebook, a monitor, a billboard and the Internet of Things. The display device 10 may be one of an organic light-emitting display device, a liquid-crystal display device, a plasma display device, a field emission display device, an electrophoretic display device, an electrowetting display device, a quantum dot light-emitting display device, a micro LED display device and the like. In the following description, an organic light-emitting display device is described as an example of the display device 10. It is, however, to be understood that embodiments are not limited thereto.

Referring to FIGS. 1 and 2, the display device 10 includes a display panel 100, a display driver 200, and a circuit board 300.

The display panel 100 may be formed in a rectangular plane having shorter sides in the first direction DR1 and longer sides in the second direction DR2 intersecting the first direction DR1. Each of the corners where the short side in the first direction DR1 meets the longer side in the second direction DR2 may be rounded with a predetermined curvature or may be a right angle. The shape of the display panel 100 when viewed from the top is not limited to a quadrangular shape, but may be formed in a different polygonal shape, a circular shape, or an elliptical shape. The display panel 100 may be, but is not limited to being, substantially flat. For example, the display panel 10 may include curved portions formed at left and right ends thereof and having a substantially constant or varying curvature. In addition, the display panel 100 may be formed to be flexible so that it may be curved, bent, folded or rolled.

The display panel 100 may include a display area DA where sub-pixels SP are formed to display images, and a non-display area NDA which is the peripheral area of the display area DA. When the display panel 100 includes a curved portion, the display area DA may be disposed on the curved portion. In such case, images of the display panel 100 may also be seen on the curved portion.

In the display area DA, scan lines SL, emission lines EL, data lines DL and first supply voltage lines VDDL connected to the sub-pixels SP may be disposed, in addition to the sub-pixels SP. The scan lines SL and the emission lines EL may extend in the first direction DR1, while the data lines DL may extend in the second direction DR2 intersecting the first direction DR1. The first supply voltage lines VDDL may extend substantially in parallel in the second direction DR2 in the display area DA. The first supply voltage lines VDDL formed substantially in parallel in the second direction DR2 in the display area DA may be connected to one another in the non-display area NDA.

Each of the sub-pixels SP may be connected to at least one of the scan lines SL, at least one of the data lines DL, at least one of the emission lines EL, and at least one of the first supply voltage lines VDDL. In the example shown in FIG. 2, each of the sub-pixels SP is connected to two scan lines SL, one data line DL, one emission line EL, and the first supply voltage line VDDL for convenience of illustration. It is, however, to be understood that embodiments are not limited thereto. For example, each of the sub-pixels SP may be connected to three scan lines SL rather than two scan lines SL.

Each of the sub-pixels SP may include a driving transistor, at least one switching transistor, a light-emitting element, and a capacitor. When the data voltage is applied to the gate electrode, the driving transistor may supply a driving current to the light-emitting element, so that light may be emitted. The driving transistor and the at least one switching transistor may be thin-film transistors (TFTs). The light-emitting element may emit light in proportion to the driving current from the driving transistor. The light-emitting element may be an organic light-emitting diode including an anode electrode, an organic emission layer, and a cathode electrode. The capacitor may keep the data voltage applied to the gate electrode of the driving transistor constant.

The non-display area NDA may be defined as the area from the outer side of the display area DA to the edge of the display panel 100. In the non-display area NDA, a scan driver 410 for applying scan signals to scan lines SL, and pads DP connected to the data lines DL may be disposed. Since the circuit board 300 is attached to the pads DP, the pads DP may be disposed on one edge of the display panel 100, e.g., the lower edge of the display panel 100.

The scan driver 410 may be connected to the display driver 200 through a plurality of first scan control lines SCL1. The scan driver 410 may receive scan control signals from the pads DP through the plurality of first scan control wires SCL1. The scan driver 410 may generate scan signals according to the scan control signals and may sequentially output the scan signals to the scan lines SL. The sub-pixels SP to which the data voltages are supplied are selected by the scan signals of the scan driver 410 and the data voltages are supplied to the selected sub-pixels SP.

An emission control driver 420 may be connected to a display driver 200 through a plurality of second scan control lines SCL2. The emission control driver 420 may receive emission control signals from the pads DP through the plurality of second scan control lines SCL2. The emission control driver 420 may generate emission control signals according to the emission control signals and may sequentially output the emission control signals to the emission lines EL.

While FIG. 2 shows that the scan driver 410 is disposed on an outer side of the display area DA, and the emission control driver 420 is disposed on the opposite side of the display area DA, embodiments are not limited thereto. For example, both the scan driver 410 and the emission control driver 420 may be disposed on an outer side of the display area DA or may be disposed on each of the outer sides of the display area DA.

The display driver 200 receives digital video data and timing signals from external devices. The display driver 200 converts the digital video data into analog positive/negative data voltages and supplies them to the data lines DL. The display driver 200 generates and supplies scan control signals for controlling the operation timing of the scan driver 410 through the first scan control lines SCL1. The display driver 200 generates and supplies emission control signals for controlling the operation timing of the emission control driver 420 through the second scan control lines SCL2. The display driver 200 may supply a first supply voltage to the first supply voltage lines VDDL.

The display driver 200 may be implemented as an integrated circuit (IC) and attached to the circuit board 300 by the chip-on-film (COF) technique. Alternatively, the display driver 200 may be attached to the display panel 100 by chip-on-glass (COG) technique, chip-on-plastic (COP) technique, or ultrasonic bonding.

The circuit board 300 may be attached to the pads DP using an anisotropic conductive film. In this manner, the lead lines of the circuit board 300 may be electrically connected to the pads DP. The circuit board 300 may be a flexible printed circuit board, a printed circuit board, or a flexible film such as a chip on film.

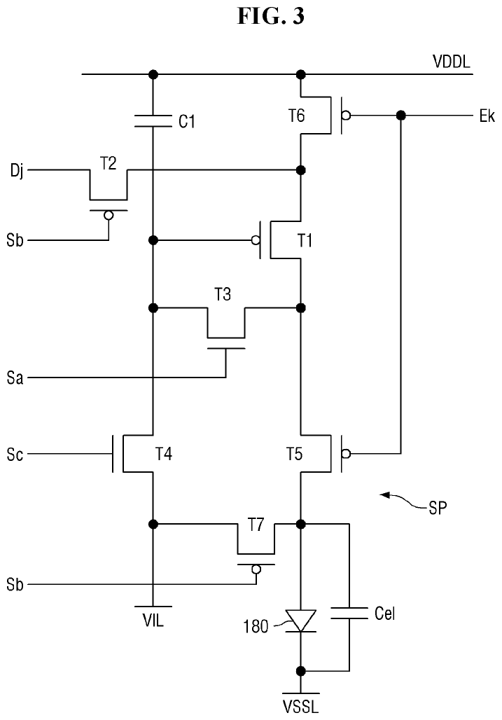

FIG. 3 is a circuit diagram of an embodiment of a representative one of the sub-pixels of FIG. 2.

In FIG. 3, a circuit of a sub-pixel SP of the display device may include a light-emitter, which may be in the form of an organic light-emitting diode 180, a plurality of transistors T1 to T7, and a capacitor C1. A data line Dj, a first scan line Sa, a second scan line Sb, a third scan line Sc, an emission line Ek, a first supply voltage line VDDL, a second supply voltage line VSSL, and an initializing voltage line VIL may be connected to the circuit of the sub-pixel.

The organic light-emitting diode 180 may include an anode electrode and a cathode electrode. The capacitor C1 may include a first electrode and a second electrode.

The plurality of transistors may include first to seventh transistors T1 to T7. Each of the transistors T1 to T7 may include a gate electrode, a first electrode, and a second electrode. One of the first electrode and the second electrode of each of the transistors T1 to T7 may be a source electrode while the other one may be a drain electrode.

Each of the transistors T1 to T7 may be a thin-film transistor. Each of the transistors T1 to T7 may be either a PMOS transistor or an NMOS transistor. In an embodiment, the first transistor T1 as a driving transistor, the second transistor T2 as a data transfer transistor, the fifth transistor T5 as a first emission control transistor, the sixth transistor T6 as a second emission control transistor and the seventh transistor T7 as a second initializing transistor are PMOS transistors. On the other hand, the third transistor T3 as a compensating transistor, and the fourth transistor T4 as a first initializing transistor are NMOS transistors. The PMOS transistors and the NMOS transistors have different characteristics. The third transistor T3 and the fourth transistor T4 are implemented with NMOS transistors having a relatively good turn-off characteristic so that leakage of the driving current during the emission period of the organic light-emitting diode OLED may be reduced.

Hereinafter, each of the elements will be described in detail.

The gate electrode of the first transistor T1 is connected to the first electrode of the capacitor C1. The first electrode of the first transistor T1 is connected to the terminal of the first supply voltage VDDL via the sixth transistor T6. The second electrode of the first transistor T1 is connected to the anode electrode of the organic light-emitting diode 180 via the fifth transistor T5. The first transistor T1 receives the data signal DATA according to the switching operation of the second transistor T2 to supply the driving current to the organic light-emitting diode 180.

The gate electrode of the second transistor T2 is connected to the terminal of the second scan line Sb. The first electrode of the second transistor T2 is connected to the terminal of the data line Dj. The second electrode of the second transistor T2 is connected to the first electrode of the first transistor T1 and is connected to the terminal of the first supply voltage VDDL through the sixth transistor T6. The second transistor T2 performs switching operation in such a manner that it is turned on in response to a signal applied to the second scan line Sb to transfer a data signal applied through a data line Dj to the first electrode of the first transistor T1.

The gate electrode of the third transistor T3 is connected to the terminal of the first scan line Sa. The first electrode of the third transistor T3 is connected to the second electrode of the first transistor T1 and is connected to the anode electrode of the organic light-emitting diode 180 via the fifth transistor T5. The second electrode of the third transistor T3 is connected to the first electrode of the capacitor C1, the first electrode of the fourth transistor T4 and the gate electrode of the first transistor T1. The third transistor T3 is turned on in response to the signal of the first scan line Sa to connect the gate electrode with the second electrode of the first transistor T1, to diode-connect the first transistor T1. Accordingly, a voltage difference equal to the threshold voltage of the first transistor T1 is generated between the first electrode and the gate electrode of the first transistor T1. Deviations in the threshold voltage of the first transistor T1 may be compensated by supplying the data signal that compensates for the threshold voltage to the gate electrode of the first transistor T1.

The gate electrode of the fourth transistor T4 is connected to the terminal of the third scan line Sc. The second electrode of the fourth transistor T4 is connected to the terminal of the initializing voltage line VIL. The first electrode of the fourth transistor T4 is connected to the first electrode of the capacitor C1, the second electrode of the third transistor T3 and the gate electrode of the first transistor T1. The fourth transistor T4 is turned on in response to the signal of the third scan line Sc to transfer the initializing voltage signal of the initializing voltage line VIL to the gate electrode of the first transistor T1, to initialize the voltage at the gate electrode of the first transistor T1.

The gate electrode of the fifth transistor T5 is connected to the terminal of the emission line Ek. The first electrode of the fifth transistor T5 is connected to the second electrode of the first transistor T1 and the first electrode of the third transistor T3. The second electrode of the sixth transistor T6 is connected to the anode electrode of the organic light-emitting diode 180.

The gate electrode of the sixth transistor T6 is connected to the terminal of the emission line Ek. The first electrode of the sixth transistor T6 is connected to the terminal of the first supply voltage VDDL. The second electrode of the sixth transistor T6 is connected to the first electrode of the first transistor T1 and the second electrode of the second transistor T2.

The fifth transistor T5 and the sixth transistor T6 are simultaneously turned on in response to the emission control signal of the emission line Ek so that the driving current flows through the organic light-emitting diode 180.

The gate electrode of the seventh transistor T7 is connected to the terminal of the second scan line Sb. The first electrode of the seventh transistor T7 is connected to the anode electrode of the organic light-emitting diode 180. The second electrode of the seventh transistor T7 is connected to the terminal of the initializing voltage VIL. The seventh transistor T7 is turned on in response to the emission control signal of the emission line Ek to initialize the anode electrode of the organic light-emitting diode 180.

While the signal of the second scan line Sb is shown as being applied to the gate electrode of the seventh transistor T7, the pixel circuit may be configured such that the emission control signal of the emission line Ek may be applied to the gate electrode of the seventh transistor T7 in another embodiment.

The second electrode of the capacitor C1 is connected to the terminal of the first supply voltage line VDDL. The first electrode of the capacitor C1 is connected to the gate electrode of the first transistor T1, the second electrode of the third transistor T3 and the first electrode of the fourth transistor T4. The cathode electrode of the organic light-emitting diode 180 is connected to the terminal of the second supply voltage line VSSL. The organic light-emitting diode 180 displays an image by receiving a driving current from the first transistor T1 to emit light.

Each of the first to seventh transistors T1, T2, T3, T4, T5, T6 and T7 may include a semiconductor layer. Some of the first to seventh transistors T1, T2, T3, T4, T5, T6 and T7 may include a semiconductor layer made of polycrystalline silicon, while some others of the first to seventh transistors T1, T2, T3, T4, T5, T6 and T7 may include a semiconductor layer made of oxide. For example, the semiconductor layers of the first to seventh transistors T1, T2, T3, T4, T5, T6 and T7 may be made of polycrystalline silicon. Alternatively, the semiconductor layers of the first transistor T1, the fifth transistor T5 to the seventh transistor T7 may be made of polycrystalline silicon while the semiconductor layers of the third transistor T3 and the fourth transistor T4 may be made of oxide. For example, the semiconductor layer of the driving transistor may include polycrystalline silicon, and the semiconductor layer of the switching transistor may include oxide.

The semiconductor layer of the switching transistor may include a first channel region overlapping the gate electrode of the switching transistor, a first drain region located on one side of the first channel region, and a first source region located on the other side of the first channel region. The semiconductor layer of the driving transistor may include a second channel region overlapping the gate electrode of the driving transistor, a second drain region located on one side of the second channel region, and a second source region located on the other side of the second channel region.

The above-described display device 10 may include a flexible material such as plastic in order to make the display device 10 flexible (e.g., foldable, rollable, and bendable). As an example, polyimide may be used in a substrate of a variety of flexible display devices to provide a flexible insulating substrate. Applicant discovered that such a substrate including polyimide may easily induce or allow charging phenomenon in which charges are collected on its surface, and the charging phenomenon causes electrical characteristics of thin-film transistors adjacent to the substrate to deteriorate or vary.

Hereinafter, features of the display device will be described that may prevent or suppress charging on the substrate to maintain electrical characteristics of thin-film transistors.

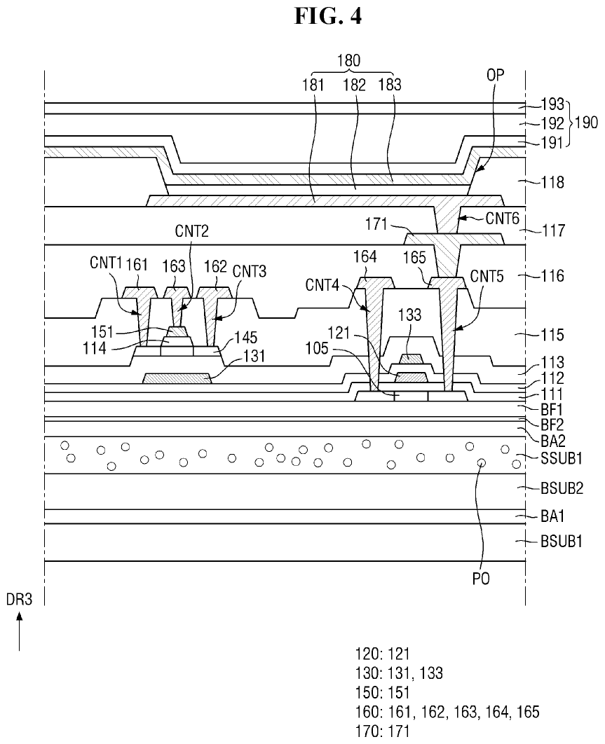

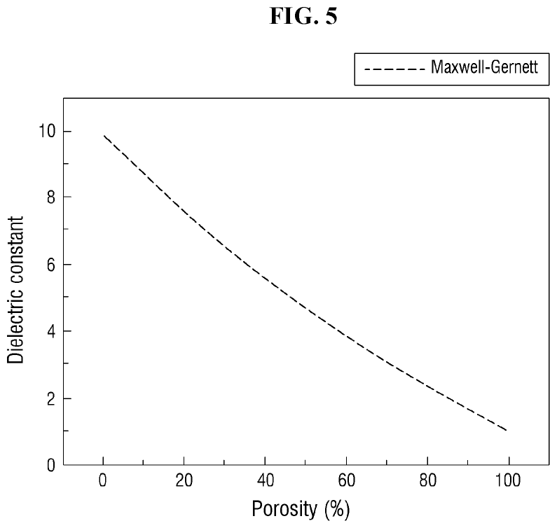

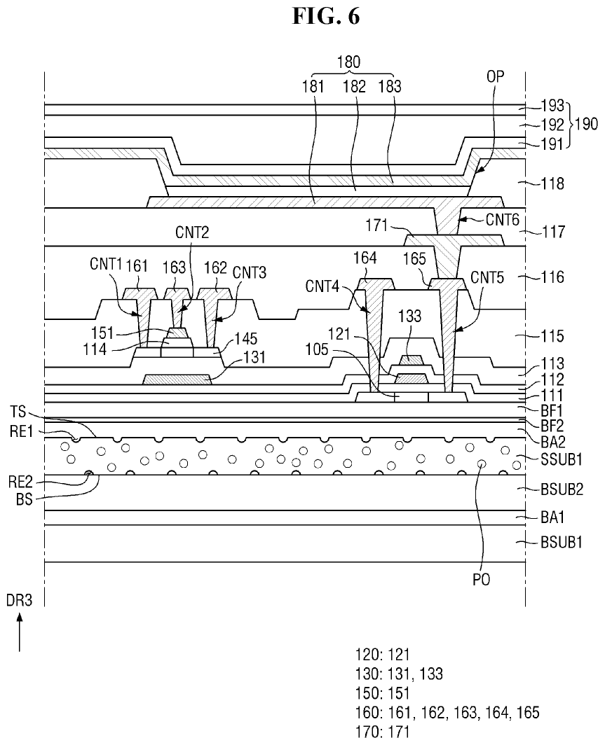

FIG. 4 is a cross-sectional view of an embodiment of a display device constructed according to the principles of the invention. FIG. 5 is a Maxwell-Garnett graph showing the dielectric constant of a thin film according to its porosity. FIG. 6 is a cross-sectional view of another embodiment of a display device constructed according to the principles of the invention.

Referring to FIG. 4, the display device 10 may include a first base substrate BSUB1, a first barrier layer BA1 disposed on the first base substrate BSUB1, a second base substrate BSUB2 disposed on the first barrier layer BA1, a first sub-substrate SSUB1 disposed on the second base substrate BSUB2, a second barrier layer BA2 disposed on the first sub-substrate SSUB1, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

Specifically, the first base substrate BSUB1 supports the layers disposed thereon. The first base substrate BSUB1 may be transparent when the organic light-emitting display device is a bottom-emission or both-sided emission type design. When the organic light-emitting display device is a top-emission type, a semitransparent or opaque substrate as well as a transparent substrate may be employed. The first base substrate BSUB1 may include a flexible material such as plastic, and may include, for example, polyimide.

The first barrier layer BA1 may be disposed on the first base substrate BSUB1. The first barrier layer BA1 may prevent impurity ions from diffusing, may prevent permeation of moisture or outside air, and may provide a substantially flat surface. The first barrier layer BA1 may include silicon nitride, silicon oxide, silicon oxynitride, or the like.

The second base substrate BSUB2 may be disposed on the first barrier layer BA1. The second base substrate BSUB2 may include a flexible material such as plastic, and may include, for example, polyimide.

The first sub-substrate SSUB1 may be disposed on the second base substrate BSUB2. The first sub-substrate SSUB1 may be an insulating substrate disposed closest to the thin-film transistors described below and may contact an inorganic layer such as the second barrier layer BA2 disposed between the thin-film transistor and the first sub-substrate SSUB1. When a voltage is applied to the gate electrode of each of the thin-film transistors, electrons are charged at the interface between the first sub-substrate SSUB1 and the second barrier layer BA2 disposed on the first sub-substrate SSUB1, and interfacial polarization may occur. The charged electrons may affect the residual DC components existing in the drain of the thin-film transistors, such that the electrons of the residual DC components may not bypass even after a period of time has elapsed and accordingly organic light-emitting diodes connected to the thin-film transistors may emit light undesirably. As a result, an afterimage is created in the display area DA of the display device 10, i.e., a specific pattern remains. Moreover, the afterimage does not disappear quickly even after the display device 10 displays another image to apply stress to the thin-film transistors. As such, the insulating substrate including materials for flexibility, such as polyimide, may cause the quality of the screen to deteriorate.

According to this embodiment, by providing the first sub-substrate SSUB1 having a dielectric constant of about 2 to about 3, it is possible to reduce the electron charging effect and suppress interfacial polarization.

A condition that causes interfacial polarization at the interface between the first sub-substrate SSUB1 and the second barrier layer BA2 may be expressed by the following relationship:

ε₁p₁≠ε₂p₂ [Relational Expression]

where ε₁ denotes the dielectric constant of the first sub-substrate SSUB1, p₁ denotes the specific resistance of the first sub-substrate SSUB1, ε₂ denotes the dielectric constant of the second barrier layer BA2, and p₂ denotes the specific resistance of the second barrier layer BA2.

Referring to the above relational expression, interfacial polarization is caused if the value of ε₁p₁ is not equal to the value of ε₂p₂. On the contrary, if the value of ε₁p₁ is equal to the value of ε₂p₂, interfacial polarization does not occur. The interfacial polarization gradually decreases as the difference between the values of ε₁p₁ and ε₂p₂ decreases. The specific resistance p1 may be larger than the specific resistance p2. Accordingly, the interfacial polarization may be suppressed by reducing the dielectric constant of the first sub-substrate SSUB1 to thereby reduce the difference between the value of ε₁p₁ of the first sub-substrate SSUB1 and the value of ε₂p₂ of the second barrier layer BA2.

According to an embodiment, the dielectric constant of the first sub-substrate SSUB1 may be smaller than that of the second barrier layer BA2. In order to reduce the dielectric constant of the first sub-substrate SSUB1, the first sub-substrate SSUB1 may include a plurality of voids that may be in the form of pores PO. In the pores PO, air exists. The dielectric constant of the pores PO is equal to about 1. The first sub-substrate SSUB1 may be polyimide, and the polyimide may have a dielectric constant of about 3 to about 4. According to an embodiment, the dielectric constant of the first sub-substrate SSUB1 may be lowered as the first sub-substrate SSUB1 includes the plurality of pores PO. The first sub-substrate SSUB1 may be a porous substrate including a plurality of pores PO, and the first and second base substrates BSUB1 and BSUB2 may be non-porous substrates.

Referring to FIG. 5, the dielectric constant of a thin film or a substrate depends on the porosity, i.e., the space occupied by the pores in a unit volume, and gradually decreases as the porosity increases.

According to an embodiment, the dielectric constant of the first sub-substrate SSUB1 may be lowered by forming the porosity of the plurality of pores PO included in the first sub-substrate SSUB1 in a range of about 10% to about 40%. The size of the pores PO may range from several nanometers to several micrometers, but embodiments are not limited thereto. The pores PO may have a variety of sizes as long as it is smaller than the thickness of the first sub-substrate SSUB1. The pores PO may have either the same size or different sizes, or may have random sizes.

A plurality of pores PO may be formed in the first sub-substrate SSUB1 as follows: a porogen compound is added and then polyimide is synthesized to prepare a polyimide composition. Subsequently, the polyimide composition is coated with a thin film, and the porogen is removed by heat treatment via a curing process to form pores in the place of the removed porogen.

Specifically, the synthesis of polyimide may be carried out by putting a dianhydride monomer and a diamine monomer in a solvent, performing condensation polymerization in the solvent to produce polyamic acid, which is a polyamide having a carboxyl group, and imidizing (dehydration reaction) the obtained polyamic acid at high temperature to produce polyimide, as expressed in Reaction Formula below:

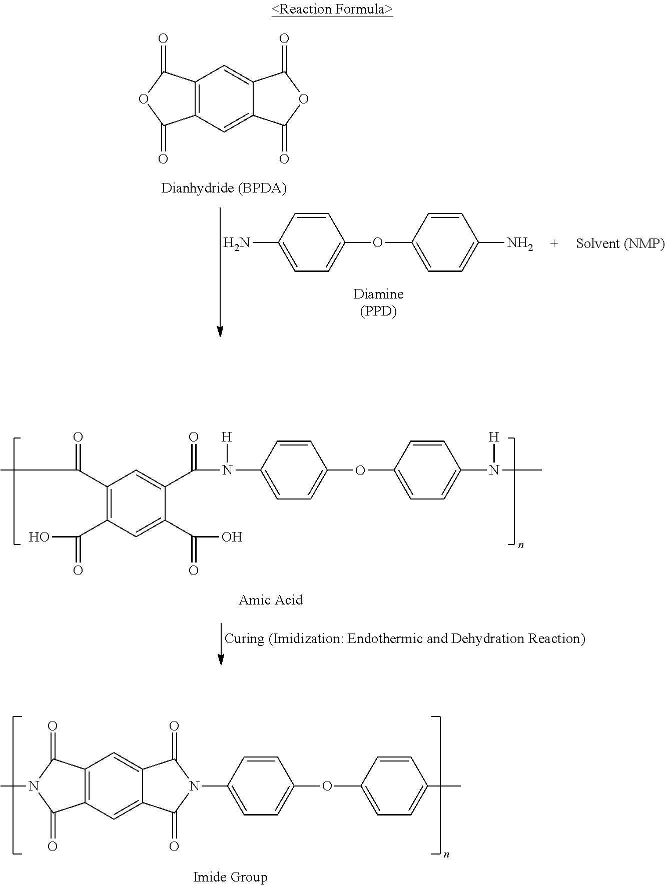

According to an embodiment, after the polyamic acid is produced, a porogen compound may be mixed.

A dianhydride monomer may be selected from the group consisting of: pyromellitic dianhydride; 2,3,6,7-naphthalenetetracarboxylic dianhydride; 1,2,5,6-naphthalenetetracarboxylic dianhydride; 1,4,5,8-naphthalenetetracarboxylic dianhydride; 3,3′4,4′-biphenyltetracarboxylic dianhydride; 2,3,2′,3′-biphenyltetracarboxylic dianhydride, bis(3,4-dicarboxyphenyl)ether dianhydride; bis(3,4-dicarboxyphenyl)diphenylsulfone dianhydride; bis(3,4-dicarboxyphenyl)methane dianhydride; 2,2-bis(3,4-dicarboxyphenyl)propane dianhydride; 1,1,1,3,3,3-hexafluoro-2,2-bis(3,4-dicarboxyphenyl)propane dianhydride; bis(3,4-dicarboxyphenyl)dimethyl silane dianhydride; 2,3,4,5-pyridinetetracarboxylic dianhydride; 1,2,3,4-butanetetracarboxylic dianhydride; 1,2,3,4-cyclobutanetetracarboxylic dianhydride; 1,2,3,4-cyclopentanetetracarboxylic dianhydride; 1,2,4,5-cyclohexanetetracarboxylic dianhydride; 2,3,5-tricarboxycyclopentylacetic acid dianhydride; 3,4-dicarboxy-1,2,3,4-tetrahydro-1-naphthalenesuccinic dianhydride; and derivatives thereof.

A diamine monomer may be selected from the group consisting of: 2,5-diaminobenzonitrile; 2-(trifluoromethyl)-1,4-benzenediamine; p-phenylenediamine; 2-chloro-1,4-benzenediamine; 2-fluoro-1,4-benzenediamine; m-phenylenediamine; 2,5-diaminotoluene; 2,6-diaminotoluene; 4,4′-diaminobiphenyl; 3,3′-dimethyl-4,4′-diaminobiphenyl; 3,3′-dimethoxy-4,4′-diaminobiphenyl; diaminodiphenylmethane; diaminodiphenyl ether; 2,2-diaminodiphenylpropane; bis(3,5-diethyl-4-aminophenyl)methane; diaminodiphenylsulfone; diaminonaphthalene; 1,4-bis(4-aminophenoxy)benzene; 4,4′-diaminobenzophenone; 3,4′-diaminobenzophenone; 1,4-bis(4-aminophenyl)benzene; 9,10-bis(4-aminophenyl)anthracene; 1,3-bis(4-aminophenoxy)benzene; 4,4′-bis(4-aminophenoxy)diphenylsulfone; 2,2-bis[4-(4-aminophenoxy)phenyl]propane; 2,2-bis(4-aminophenyl)hexafluoropropane; 2,2-bis[4-(4-aminophenoxy)phenyl]hexafluoropropane; bis(4-aminocyclohexyl)methane; tetramethylenediamine; hexamethylene diamine; bis(3-aminopropyl) tetramethyldisiloxane; and derivatives thereof.

The solvent may be dimethylfuran (DMF) or N-methyl pyrrolidone (NMP).

Any organic, inorganic, or organic-inorganic material may be used as the porogen compound as long as it may be decomposed at 400° C. or lower and form pores. The porogen compound may be selected from the group consisting of: a polymeric dendrimer; a degradable linear polymer such as polyester, polystyrene, PMS, polyacrylate, PMA, polycarbonate and polyether; a polynorbone based polymer; an organic solvent having a high boiling point, such as tetradecane; cyclodextrin based derivatives; an ionic surfactant such as C16TMABr (TMA, trimethylammonium); a nonionic surfactant such as polyethylene oxide (PEO)-polyphenylene oxide (PPO)-polyethylene oxide (PEO); and polyalkylene oxide, poly(caprolactone), poly(valeractone), and poly(methylmethacrylate).

According to another embodiment, a polyamic acid may be prepared by mixing a dianhydride monomer, a diamine monomer and a porogen compound in a solvent and then synthesizing them.

The polyimide composition thus prepared may be coated on a substrate. It may be coated via a solution process such as spin coating, spray coating and slit coating.

The coated polyimide thin film is finally produced into a polyimide thin film via a curing process. During this curing process, the porogen compound included in the polyimide thin film may be decomposed and removed, such that pores may be formed where they have been removed.

The curing process may be carried out at the high temperature of 470° C. for several minutes to several hours, such that the porogen compound may be removed and simultaneously the polyimide thin film may be cured. According to another embodiment, during a curing process, a porogen compound may be removed first at a temperature of 400° C. or less, and then a polyimide thin film may be cured at the high temperature of 470° C. for several minutes to several hours.

The second barrier layer BA2 may be disposed on the first sub-substrate SSUB1. The second barrier layer BA2 may prevent impurity ions from diffusing, may prevent permeation of moisture or outside air, and may provide a flat surface. The second barrier layer BA2 may include silicon nitride, silicon oxide, silicon oxynitride, or the like.

The second buffer layer BF2 may be disposed on the second barrier layer BA2. The second buffer layer BF2 serves to supply hydrogen to a polysilicon semiconductor layer 105 to be described later. The second buffer layer BF2 may include silicon nitride, silicon oxide, silicon oxynitride, etc., and preferably may include silicon nitride.

The first buffer layer BF1 may be disposed on the second buffer layer BF2. The first buffer layer BF1 may include silicon nitride, silicon oxide, silicon oxynitride, or the like. As such, one or more inorganic layers may be disposed between and/or on substrates (e.g., BSUB1, BSUB2, and SSUB1) of the display device 10. The first barrier layer BA1, the second barrier layer BA2, the second buffer layer BF2 and the first buffer layer BF1 described above may be inorganic layers.

The polycrystalline silicon semiconductor layer 105 may be disposed on the buffer layer 1. The polycrystalline silicon semiconductor layer 105 may be made of amorphous silicon or poly silicon. The crystalline silicon may be produced by crystallizing amorphous silicon. Examples of the crystallizing techniques may include, but is not limited to, rapid thermal annealing (RTA), solid phase crystallization (SPC), excimer laser annealing (ELA), metal induced crystallization (MIC), metal induced lateral crystallization (MILC), sequential lateral solidification (SLS), etc.

The polycrystalline silicon semiconductor layer 105 may include a second channel region overlapping the second gate electrode 121 in the thickness direction, i.e., the third direction DR3, a second drain region located on one side of the second channel region, and a second source region located on the other side of the second channel region.

A lower gate insulating layer 111 may be disposed on the polycrystalline silicon semiconductor layer 105. The lower gate insulating layer 111 may be a gate insulating film having a gate insulating function. The lower gate insulating layer 111 may include a silicon compound, a metal oxide, etc. For example, the lower gate insulating layer 111 may include silicon oxide, silicon nitride, silicon oxynitride, aluminum oxide, tantalum oxide, hafnium oxide, zirconium oxide, titanium oxide, etc. They may be used alone or in combinations. The lower gate insulating layer 111 may be made up of a single layer or multiple layers of different materials stacked on one another.

A first conductive layer 120 may be disposed on the lower gate insulating layer 111. The first conductive layer 120 may include the second gate electrode 121. The first conductive layer 120 may include at least one metal selected from the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The first conductive layer 120 may be made up of a single layer or multiple layers.

An upper gate insulating layer 112 may be disposed on the first conductive layer 120 including the second gate electrode 121. The upper gate insulating layer 112 may be a gate insulating film having a gate insulating function. The upper gate insulating layer 112 may include a silicon compound, a metal oxide, etc. For example, the upper gate insulating layer 112 may include silicon oxide, silicon nitride, silicon oxynitride, aluminum oxide, tantalum oxide, hafnium oxide, zirconium oxide, titanium oxide, etc. They may be used alone or in combinations. The upper gate insulating layer 112 may be made up of a single layer or multiple layers of different materials stacked on one another.

A second conductive layer 130 may be disposed on the upper gate insulating layer 112. The second conductive layer 130 may include at least one metal selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The second conductive layer 130 may be made up of a single layer or multiple layers.

The second conductive layer 130 may include a first lower gate electrode 131 and a capacitor electrode 133. The first lower gate electrode 131 may be disposed to overlap with the first channel region of the oxide semiconductor layer 145 in the thickness direction. The capacitor electrode 133 may be disposed to overlap with the second channel region of the polycrystalline silicon semiconductor layer 105 in the thickness direction.

A lower interlayer dielectric layer 113 may be disposed on the second conductive layer 130. The lower interlayer dielectric layer 113 may include a silicon compound, a metal oxide, etc. For example, the lower interlayer dielectric layer 113 may include silicon oxide, silicon nitride, silicon oxynitride, aluminum oxide, tantalum oxide, hafnium oxide, zirconium oxide, titanium oxide, etc. They may be used alone or in combinations. The lower interlayer dielectric layer 113 may be made up of a single layer or multiple layers of different materials stacked on one another.

The oxide semiconductor layer 145 may be disposed on the lower interlayer dielectric layer 113. The oxide semiconductor layer 145 may include oxide. The oxide may include one or more oxides selected from zinc (Zn), indium (In), gallium (Ga), tin (Sn) cadmium (Cd), germanium (Ge) hafnium (Hf), or a combination thereof. The oxide may include at least one of indium-gallium-zinc oxide (IGZO), zinc-tin oxide (ZTO), indium-tin oxide (IZO), etc.

A first gate insulating layer 114 may be disposed on the oxide semiconductor layer 145. The first gate insulating layer 114 may be a gate insulating film having a gate insulating function. The first gate insulating layer 114 may include a silicon compound, a metal oxide, etc. For example, the first gate insulating layer 114 may include silicon oxide, silicon nitride, silicon oxynitride, aluminum oxide, tantalum oxide, hafnium oxide, zirconium oxide, titanium oxide, etc. They may be used alone or in combinations. The first gate insulating layer 114 may be made up of a single layer or multiple layers of different materials stacked on one another.

A portion of the upper surface of the first source region and the first drain region of the oxide semiconductor layer 145 may be exposed by the first gate insulating layer 114. The first gate insulating layer 114 may be disposed to overlap the first channel region of the oxide semiconductor layer 145 in the thickness direction and may be disposed not to overlap the first source region and the first drain region.

A third conductive layer 150 may be disposed on the first gate insulating layer 114. The third conductive layer 150 may include at least one metal selected from the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The third conductive layer 150 may be made up of a single layer or multiple layers.

The third conductive layer 150 may include a first upper gate electrode 151. The first upper gate electrode 151 may be disposed to overlap the first gate insulating layer 114 in the thickness direction.

According to an embodiment, the gate electrode of the switching transistor may be a double gate electrode including a first upper gate electrode 151 and a first lower gate electrode 131. The first upper gate electrode 151 may be electrically connected to the first lower gate electrode 131. The capacitor electrode 133 and the second gate electrode 121 may form a capacitor by interposing the upper gate insulating layer 112 therebetween.

An upper interlayer dielectric layer 115 may be disposed on the second conductive layer 150. The upper interlayer dielectric layer 115 may cover the first upper gate electrode 151, the side surfaces of the first gate insulating layer 114, and the exposed upper surface of the oxide semiconductor layer in the first source region and the first drain region. The upper interlayer dielectric layer 115 may include a silicon compound, a metal oxide, etc. For example, the upper interlayer dielectric layer 115 may include silicon oxide, silicon nitride, silicon oxynitride, aluminum oxide, tantalum oxide, hafnium oxide, zirconium oxide, titanium oxide, etc. They may be used alone or in combinations. The upper interlayer dielectric layer 115 may be made up of a single layer or multiple layers of different materials stacked on one another.

The fourth conductive layer 160 may be disposed on the upper interlayer dielectric layer 115. The fourth conductive layer 160 may include at least one metal selected from the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The fourth conductive layer 160 may be made up of a single layer or multiple layers.

The fourth conductive layer 160 may include a first source electrode 161, a first drain electrode 162, a second source electrode 164, and a second drain electrode 165. The fourth conductive layer 160 may further include a first connection electrode 163.

The first source electrode 161 and the first drain electrode 162 may be connected to the first source region and the first drain region through the contact holes CNT1 and CNT3 penetrating the upper interlayer insulating layer 115, respectively. The second source electrode 164 and the second drain electrode 165 may be connected to the second source region and the second drain region of the polycrystalline silicon semiconductor layer 105 through the contact holes CNT4 and CNT5 penetrating the upper interlayer dielectric layer 115, the lower interlayer dielectric layer 113 and the gate insulating layers 111 and 112, respectively. The polycrystalline silicon semiconductor layer 105, the second gate electrode 121, the second source electrode 164, and the second drain electrode 165 may form a driving transistor, such as the first transistor T1 of FIG. 3. The oxide semiconductor layer 145, the first lower gate electrode 131, the first upper gate electrode 151, and the first source electrode 161, and the first drain electrode 162 may form a switching transistor to transmit a data signal from a data line to the driving transistor, such as the second transistor T2 of FIG. 3.

The first connection electrode 163 may be connected to the first upper gate electrode 151 through a contact hole CNT2 penetrating through the upper interlayer dielectric layer 115. The first connection electrode 163 is electrically connected to the first upper gate electrode 151, so that the resistance of the first upper gate electrode 151 may be reduced.

A first via layer 116 may be disposed over the fourth conductive layer 160. The first via layer 116 may include an inorganic insulating material or an organic insulating material such as polyacrylate resin, epoxy resin, phenolic resin, polyamide resin, polyimide resin, unsaturated polyesters resin, poly phenylen ether resin, poly phenylene sulfide resin, and benzocyclobutene (BCB). The first via layer 116 may be made up of a single layer or multiple layers of different materials stacked on one another.

A fifth conductive layer 170 may be disposed on the first via layer 116. The fifth conductive layer 170 may include a second connection electrode 171. The fifth conductive layer 170 may include at least one metal selected from the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The fifth conductive layer 170 may be made up of a single layer or multiple layers.

The second connection electrode 171 may be connected to the second drain electrode 165 through a sixth contact hole CNT6 that partially penetrates the first via layer 116 to expose the upper surface of the second drain electrode 165.

An anode electrode 181 may be disposed on the first via layer 116. The anode electrode 181 may be connected to the second connection electrode 171 through a contact hole penetrating the first via layer 116. The anode electrode 181 may be separately disposed for each sub-pixel SP (see FIG. 2). For example, the anode electrode 181 may be a pixel electrode.

A bank layer 118 may be disposed on the anode electrode 181. The bank layer 118 may include an opening OP partially exposing the anode electrode 181. The bank layer 118 may be made of an organic insulating material or an inorganic insulating material. For example, the bank layer 118 may include at least one of: a photoresist, a polyimide resin, an acrylic resin, a silicon compound, a polyacrylic resin, and the like.

An organic emission layer 182 may be disposed on the upper surface of the anode electrode 181 and in the opening OP of the bank layer 118. A cathode electrode 183 may be disposed on the organic emission layer 182 and the bank layer 118. The cathode electrode 183 may be a common electrode disposed across a plurality of pixels.

The anode electrode 181, the organic emission layer 182 and the cathode electrode 183 may form an organic light-emitting diode 180.

An encapsulation layer 190 may be disposed on the cathode electrode 183. The encapsulation layer 190 may cover the organic light-emitting diode 180. The encapsulation layer 190 may be a stack of inorganic layers and organic layers alternately stacked on one another. For example, the encapsulation layer 190 may include a first inorganic encapsulation layer 191, an organic encapsulation layer 192 and a second inorganic encapsulation layer 193 stacked on one another in this order.

Incidentally, as described above, in order to form the pores PO in the first sub-substrate SSUB1, a porogen compound may be mixed and thermally decomposed.

Referring to FIG. 6, according to another embodiment, when the porogen compound located on the outermost surfaces of the first sub-substrate SSUB1 is thermally decomposed, pores may form where the porogen compound was, and thus a plurality of recesses RE1 and RE2 may be formed on the surfaces.

The first sub-substrate SSUB1 may include a plurality of recesses RE1 and RE2 on the top surface TS and the bottom surface BS, respectively. The plurality of recesses RE1 and RE2 may include first recesses RE1 that are concavely recessed from the top surface TS of the first sub-substrate SSUB1 toward the first base substrate BSUB1. In addition, the plurality of recesses RE1 and RE2 may include second recesses RE2 that are concavely recessed from the bottom surface BS of the first sub-substrate SSUB1 toward the second barrier layer BA2.

The size of the first recesses RE1 and the second recesses RE2 may be substantially equal to the size (e.g., diameter) of the pores PO included in the first sub-substrate SSUB1. The size of the first recesses RE1 and the second recesses RE2 may range from several nanometers to several tens of micrometers. The first recesses RE1 and the second recesses RE2 may be arranged regularly or irregularly.

The second barrier layer BA2 may be disposed on the first sub-substrate SSUB1. The second barrier layer BA2 may be in contact with a surface, i.e., the top surface TS of the first sub-substrate SSUB1, and the plurality of first recesses RE1 may be filled with the second barrier layer BA2. Specifically, the second barrier layer BA2 may be used to fill the plurality of first recesses RE1 of the first sub-substrate SSUB1 to provide a flat surface over the first sub-substrate SSUB1, and thus may prevent deterioration of the physical properties of the first sub-substrate SSUB1 as a substrate.

According to an embodiment, the bottom surface of the second barrier layer BA2 may be disposed closer to the first base substrate BSUB1 than the top surface of the first sub-substrate SSUB1. Also, the top surface of the first sub-substrate SSUB1 may be disposed more distant from the first base substrate BSUB1 than the bottom surface of the second barrier layer BA2.

According to an embodiment, the first sub-substrate SSUB1 may be disposed on the second base substrate BSUB2. The second base substrate BSUB2 may be in contact with the bottom surface BS of the first sub-substrate SSUB1. The plurality of second recesses RE2 of the first sub-substrate SSUB1 may be spaced apart from the second base substrate BSUB2. The plurality of second recesses RE2 may act as pores between the first sub-substrate SSUB1 and the second base substrate BSUB2. The second base substrate BSUB2 may be disposed under the first sub-substrate SSUB1 to support the first sub-substrate SSUB1, so that it is possible to prevent or reduce deterioration of physical properties of the first sub-substrate SSUB1.

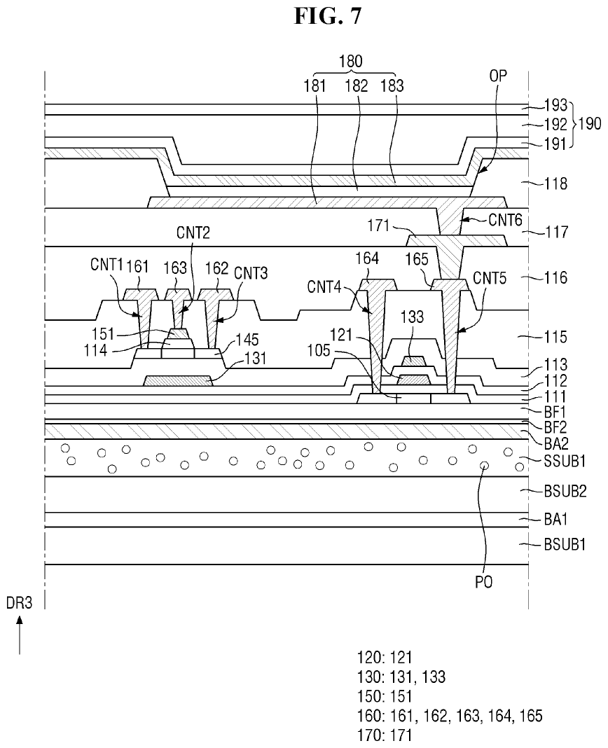

FIG. 7 is a cross-sectional view of still another embodiment of a display device constructed according to the principles of the invention.

Referring to FIG. 7, the display device 10 may include a first base substrate BSUB1, a first barrier layer BA1 disposed on the first base substrate BSUB1, a second base substrate BSUB2 disposed on the first barrier layer BA1, a first sub-substrate SSUB1 disposed on the second base substrate BSUB2, a second barrier layer BA2 disposed on the first sub-substrate SSUB1, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 7 is substantially identical to the embodiments of FIGS. 4 and 6 except that a second barrier layer BA2 in contact with a first sub-substrate SSUB1 having a low dielectric constant; and, therefore, repetitive descriptions will be omitted to avoid redundancy.

Referring to FIG. 7, the second barrier layer BA2 may be disposed on the first sub-substrate SSUB1 including a plurality of pores PO. The second barrier layer BA2 forms an interface in contact with the first sub-substrate SSUB1, and electron charging may occur at the interface between the first sub-substrate SSUB1 and the second barrier layer BA2 when a voltage is applied to adjacent a thin film transistor, such as the driving transistor and/or the switching transistor.

According to this embodiment, the dielectric constant of the second barrier layer BA2 may be lowered to suppress the electron charging. In order to lower the dielectric constant of the second barrier layer BA2, the second barrier layer BA2 may be made of a material having a low dielectric constant or may include a plurality of voids that may be in the form of pores PO.

Specifically, as an approach for lowering the dielectric constant of the second barrier layer BA2, a material having a dielectric constant of about 3.5 or less, e.g., a polymer or a silica-based material may be included in the second barrier layer BA2. The polymer may be at least one selected from the group consisting of: polytetrafluoroethylene (PTFE), poly(p-phenylene biphenyltetracarboximide) (BPDA-PDA), crosslinked polyacrylic ester emulsion (PAE), fluorinated polyacrylic ester emulsion (PAE), SiLK, benzocyclobutene (BCB), Parylene-N, and Parylene-F. The silica-based material may be at least one selected from the group consisting of: porous silica, poly silsesquioxane (PSSQ), hydro silsesquioxane (HSQ), methyl silsesquioxane (MSQ), organo silicate glass (OSG), and F doped silica glass (FSG). It should be noted that the second barrier layer BA2 is not limited to the above-listed materials. Other insulating materials having a dielectric constant of about 3.5 or less, for example, a fluorinated or hydrogenated amorphous carbon polymer, zeolite, tetraethoxy orthosilicate (TEOS), etc. may be used.

According to an embodiment, the second barrier layer BA2 may be formed by chemical vapor deposition (CVD) or coating.

The chemical vapor deposition may be carried out by using, for example, silsesquioxane. A silsesquioxane-based precursor and a silica-based dopant are prepared. The silica-based dopant may introduce Si—F, Si—R instead of Si—H or Si—(OCH₂CH₂), where R denotes alkyl, aryl or hydrogen. For example, fluorosilane (SiH₂F₂) or alkylsilane ((CH₃)xSiHy (x+y=4)) may be introduced instead of silane (SiH₄).

The prepared silsesquioxane-based precursor and silica-based dopant are used as sources of chemical vapor deposition and deposited on a substrate. When the deposited thin film is heat-treated at the high temperature of 400° C., hydrocarbons (CHx) are decomposed to generate pores, thereby forming the second barrier layer BA2 including a plurality of pores. After the second barrier layer BA2 has been formed, wet etching may be carried out using hydrogen fluoride (HF), so that it is possible to further increase the size of the pores to thereby further increase the porosity.

According to another embodiment, the coating may be carried out by using, for example, polysilsesquioxane (PSSQ). The polysilsesquioxane is mixed with a solvent. In doing so, in (—Si—O)₃—Si—(OR) of polysilsesquioxane, R may introduce a carbon-based material such as an alkyl and benzyl group or hydrogen.

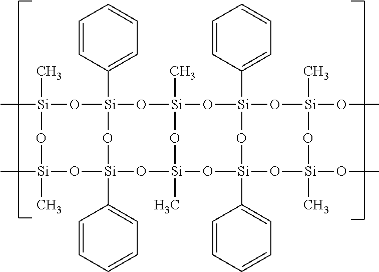

### Polysilsesquioxane

The solution is coated on a substrate by spin coating, slit coating, or the like, soft baking is carried out at a temperature of 250° C. or lower for several minutes to several hours, and hard baking is carried out at a temperature of 350° C. to 600° C. for several minutes to several hours. At this time, the methyl group (CH₃) disposed at the terminal of the polysilsesquioxane does not bond with the adjacent silica (Si) but is spaced apart from it, thereby forming nano-sized pores. That is to say, a thin film in the form of a xerogel having a plurality of nano-sized pores may be formed.

According to yet another embodiment, the polysilsesquioxane and the porogen compound may be mixed with a solvent, and then the porogen compound may be thermally decomposed during hard baking, to form pores.

According to yet another embodiment, the polysilsesquioxane may be formed by mixing the polysilsesquioxane with a solvent having a boiling point higher than the temperature at which the crosslinking reaction of the polysilsesquioxane occurs. During the baking, a crosslinking reaction of polysilsesquioxane may occur first to form a solid network, and then the solvent having a high boiling point is evaporated, such that pores may be formed.

According to yet another embodiment, the dielectric constant of the second barrier layer BA2 may be lowered by forming a polymer or silica-based material among materials having a dielectric constant of about 3.5 or less as a thin film, and then by performing post-treatment with at least one of fluorine (F), boron (B), phosphorus (P), arsenic (As) and argon (Ar). The post-treatment may be carried out by one of gas surface treatment, plasma treatment, and ion implantation. For example, the gas surface treatment may be carried out by injecting N₂ and F₂ gas or BF₃ gas to a substrate on which a thin film is formed at a temperature of approximately 55° C., to implant fluorine or boron into the second barrier layer BA2. The plasma treatment may be carried out by using a CF₄ or SF₆ gas containing fluorine or a BF₃ gas containing boron on the substrate on which the thin film is formed. The ion implantation may be carried out by implanting ions using BF₃ gas, and may additionally activate them using a laser.

When the second barrier layer BA2 is formed by the above-described thin-film forming process, for example, the chemical vapor deposition, it may be deposited with a low power in order to prevent that damage is applied to the first sub-substrate SSUB1 disposed thereunder and thus charges gather.

As described above, the dielectric constant of the second barrier layer BA2 may be lowered by including a polymer or silica-based material having a low dielectric constant in the second barrier layer BA2 or by forming pores therein. By doing so, the electron charging at the interface with the first sub-substrate SSUB1 may be reduced.

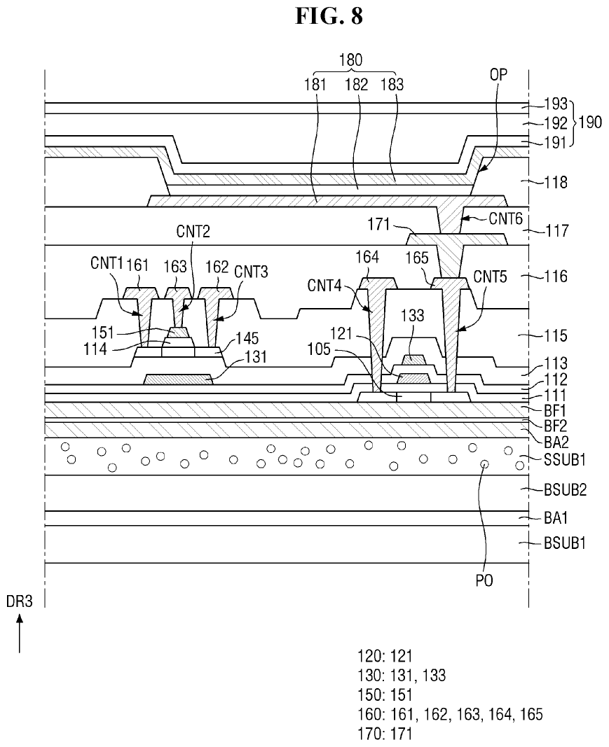

FIG. 8 is a cross-sectional view of yet another embodiment of a display device constructed according to the principles of the invention.

Referring to FIG. 8, the display device 10 may include a first base substrate BSUB1, a first barrier layer BA1 disposed on the first base substrate BSUB1, a second base substrate BSUB2 disposed on the first barrier layer BA1, a first sub-substrate SSUB1 disposed on the second base substrate BSUB2, a second barrier layer BA2 disposed on the first sub-substrate SSUB1, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 8 is substantially identical to the embodiment of FIG. 7 except that the first buffer layer BF1 in contact with a polysilicon semiconductor layer 105 has a low dielectric constant; and, therefore, repetitive descriptions will be omitted to avoid redundancy.

Referring to FIG. 8, the first buffer layer BF1 may be disposed under the polysilicon semiconductor layer 105 in contact with it. Since the first buffer layer BF1 is disposed in contact with the polysilicon semiconductor layer 105, if electron charging or interfacial polarization occurs in the first buffer layer BF1, the characteristics of the thin-film transistors may be greatly affected.

According to an embodiment, the first buffer layer BF1 may be made of a material having a low dielectric constant or may include a plurality of pores PO. The configuration of the first buffer layer BF1 may be substantially identical to the configuration of the above-described second barrier layer BA2 of FIG. 6. Specifically, the first buffer layer BF1 may include a material having a dielectric constant of about 3.5 or less, e.g., a polymer or a silica-based material, and may further include a plurality of pores PO.

Accordingly, the dielectric constant of the first buffer layer BF1 according to the illustrated embodiment of FIG. 8 may be lowered by including a polymer or silica-based material having a low dielectric constant therein or by forming pores therein. Accordingly, it is possible to prevent deterioration and/or variation of characteristics of the thin-film transistors by suppressing electron charging and interfacial polarization on the first buffer layer BF1.

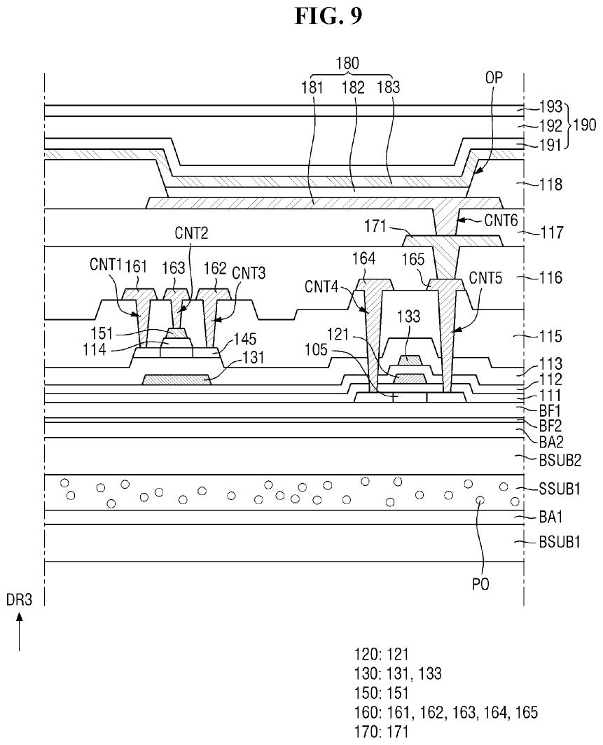

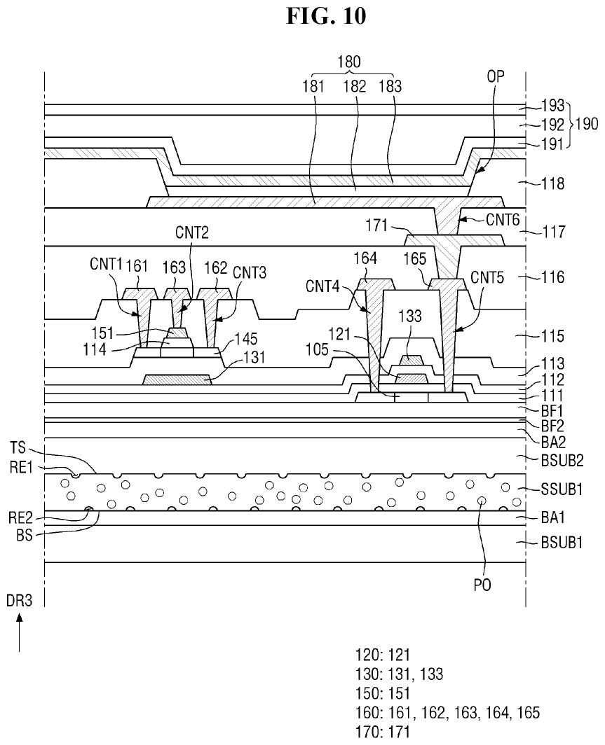

FIG. 9 is a cross-sectional view of another embodiment of a display device constructed according to the principles of the invention. FIG. 10 is a cross-sectional view of yet another embodiment of a display device constructed according to the principles of the invention.

Referring to FIG. 9, the display device 10 may include a first base substrate BSUB1, a first barrier layer BA1 disposed on the first base substrate BSUB1, a first sub-substrate SSUB1 disposed on the first barrier layer BA1, a second base substrate BSUB2 disposed on the first sub-substrate SSUB1, a second barrier layer BA2 disposed on the second base substrate BSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 9 is substantially identical to the embodiments of FIGS. 4 and 6 except that a first sub-substrate SSUB1 is disposed under a second base substrate BSUB2; and, therefore, repetitive descriptions will be omitted to avoid redundancy.

Referring to FIG. 9, a first barrier layer BA1 may be disposed on a first base substrate BSUB1, a first sub-substrate SSUB1 may be disposed on the first barrier layer BA1, and a second base substrate BSUB2 may be disposed on the first sub-substrate SSUB1.

According to this embodiment, the first sub-substrate SSUB1 may have a dielectric constant of about 3 or less. In order to reduce the dielectric constant of the first sub-substrate SSUB1, the first sub-substrate SSUB1 may include a plurality of pores PO. The dielectric constant of the first sub-substrate SSUB1 may be lowered by forming the porosity of the plurality of pores PO included in the first sub-substrate SSUB1 in a range of about 10% to 40%.

As described above, in order to form the pores PO in the first sub-substrate SSUB1, a porogen compound may be mixed and thermally decomposed.

Referring to FIG. 10, according to another embodiment, when the porogen compound located on the surfaces of the first sub-substrate SSUB1 is thermally decomposed, pores may form where the porogen compound was, and thus a plurality of recesses RE1 and RE2 may be formed on the surfaces.

The first sub-substrate SSUB1 may include a plurality of recesses RE1 and RE2 on the top surface TS and the bottom surface BS, respectively. The plurality of recesses RE1 and RE2 may include first recesses RE1 that are concavely recessed from the top surface TS of the first sub-substrate SSUB1 toward the first base substrate BSUB1. In addition, the plurality of recesses RE1 and RE2 may include second recesses RE2 that are concavely recessed from the bottom surface BS of the first sub-substrate SSUB1 toward the second barrier layer BA2.

The size of the first recesses RE1 and the second recesses RE2 may be substantially equal to the size of the pores PO included in the first sub-substrate SSUB1. The size of the first recesses RE1 and the second recesses RE2 may range from several nanometers to several tens of micrometers. The first recesses RE1 and the second recesses RE2 may be arranged regularly or irregularly.

The second base substrate BSUB2 may be disposed on the first sub-substrate SSUB1. The second base substrate BSUB2 may be in contact with a surface, i.e., the top surface TS of the first sub-substrate SSUB1, and the plurality of first recesses RE1 may be filled with the second base substrate BSUB2. Specifically, the second base substrate BSUB2 may be used to fill the plurality of first recesses RE1 of the first sub-substrate SSUB1 to provide a flat surface over the first sub-substrate SSUB1, and thus may prevent deterioration of the physical properties of the first sub-substrate SSUB1 as a substrate.

According to an embodiment, the bottom surface of the second base substrate BSUB2 may be disposed closer to the first base substrate BSUB1 than the top surface of the first sub-substrate SSUB1. Also, the top surface of the first sub-substrate SSUB1 may be disposed more distant from the first base substrate BSUB1 than the bottom surface of the second base substrate BSUB2.

According to an embodiment, the first sub-substrate SSUB1 may be disposed on the first barrier layer BA1. The first barrier layer BA1 may be in contact with the bottom surface BS of the first sub-substrate SSUB1. The plurality of second recesses RE2 of the first sub-substrate SSUB1 may be spaced apart from the first barrier layer BA1. The plurality of second recesses RE2 may act as pores between the first sub-substrate SSUB1 and the first barrier layer BA1. The first barrier layer BA1 may be disposed under the first sub-substrate SSUB1 to support the first sub-substrate SSUB1, so that it is possible to prevent deterioration of physical properties of the first sub-substrate SSUB1.

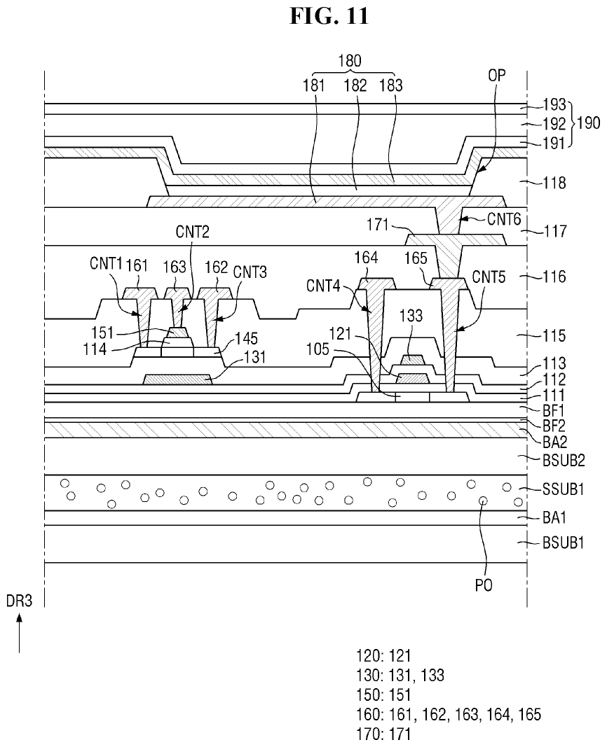

FIG. 11 is a cross-sectional view of still another embodiment of a display device constructed according to the principles of the invention.

Referring to FIG. 11, the display device 10 may include a first base substrate BSUB1, a first barrier layer BA1 disposed on the first base substrate BSUB1, a first sub-substrate SSUB1 disposed on the first barrier layer BA1, a second base substrate BSUB2 disposed on the first sub-substrate SSUB1, a second barrier layer BA2 disposed on the second base substrate BSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 11 is substantially identical to the embodiment of FIG. 9 except that a second barrier layer BA2 in contact with a second base substrate BSUB2 has a low dielectric constant; and, therefore, repetitive descriptions will be omitted to avoid redundancy.

Referring to FIG. 11, a second base substrate BSUB2 may be disposed on a first sub-substrate SSUB1 including a plurality of pores PO, and a second barrier layer BA2 may be disposed on a second base substrate BSUB2. The second barrier layer BA2 forms an interface in contact with the second base substrate BSUB2, and electron charging may occur at the interface between the second base substrate BSUB2 and the second barrier layer BA2.

According to this embodiment, the dielectric constant of the second barrier layer BA2 may be lowered to suppress the electron charging. In order to lower the dielectric constant of the second barrier layer BA2, the second barrier layer BA2 may be made of a material having a low dielectric constant or may include a plurality of pores PO. The second barrier layer BA2 may be substantially identical to the second barrier layer BA2 of FIG. 7 described above.

As described above, according to the embodiment of FIG. 11, the second barrier layer BA2 having a low dielectric constant is formed on the second base substrate BSUB2, so that it is possible to reduce the electron charging that occurs at the interface between the second base substrate BSUB2 and the second barrier layer BA2.

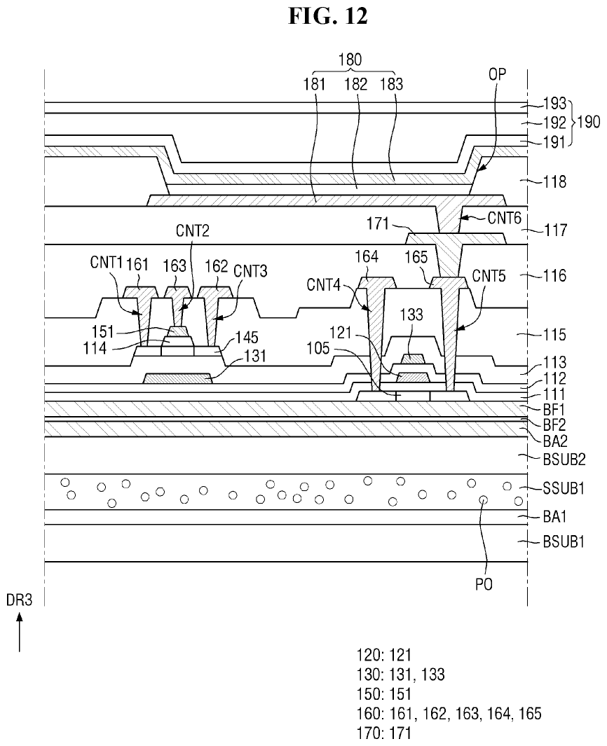

FIG. 12 is a cross-sectional view of still yet another embodiment of a display device constructed according to the principles of the invention.

Referring to FIG. 12, the display device 10 may include a first base substrate BSUB1, a first barrier layer BA1 disposed on the first base substrate BSUB1, a first sub-substrate SSUB1 disposed on the first barrier layer BA1, a second base substrate BSUB2 disposed on the first sub-substrate SSUB1, a second barrier layer BA2 disposed on the second base substrate BSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 12 is substantially identical to the embodiment of FIG. 11 except that the first buffer layer BF1 in contact with a polysilicon semiconductor layer 105 has a low dielectric constant; and, therefore, repetitive descriptions will be omitted to avoid redundancy.

Referring to FIG. 12, the first buffer layer BF1 may be disposed under the polysilicon semiconductor layer 105 in contact with it. Since the first buffer layer BF1 is disposed in contact with the polysilicon semiconductor layer 105, if electron charging occurs in the first buffer layer BF1, the characteristics of the thin-film transistors may be greatly affected.

According to an embodiment, the first buffer layer BF1 may be made of a material having a low dielectric constant or may include a plurality of pores PO. The configuration of the first buffer layer BF1 may be substantially identical to the configuration of the above-described second barrier layer BA2 of FIG. 6. Specifically, the first buffer layer BF1 may include a material having a dielectric constant of about 3.5 or less, e.g., a polymer or a silica-based material, and may further include a plurality of pores PO.

Accordingly, the dielectric constant of the first buffer layer BF1 according to the illustrated embodiment of FIG. 12 may be lowered by including a polymer or silica-based material having a low dielectric constant therein or by forming pores therein. By doing so, it is possible to prevent deterioration of and/or variation in the characteristics of the thin-film transistors by reducing electron charging and interfacial polarization on the first buffer layer BF1.

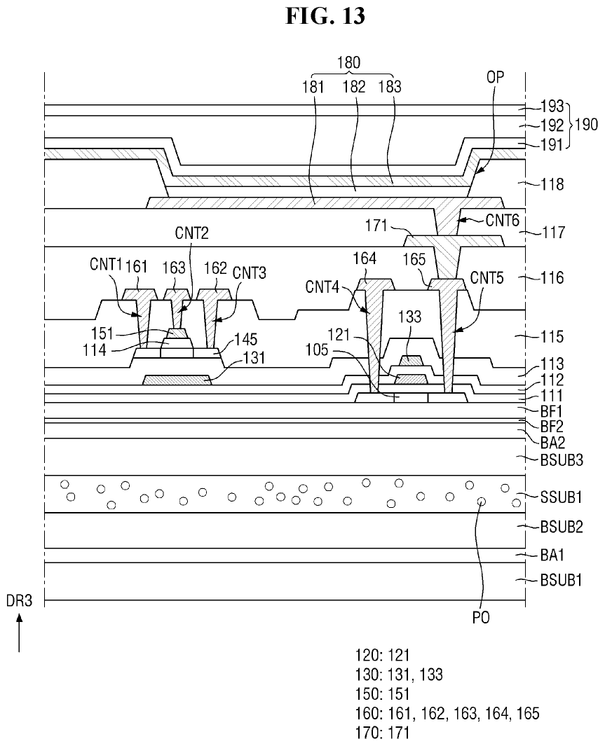

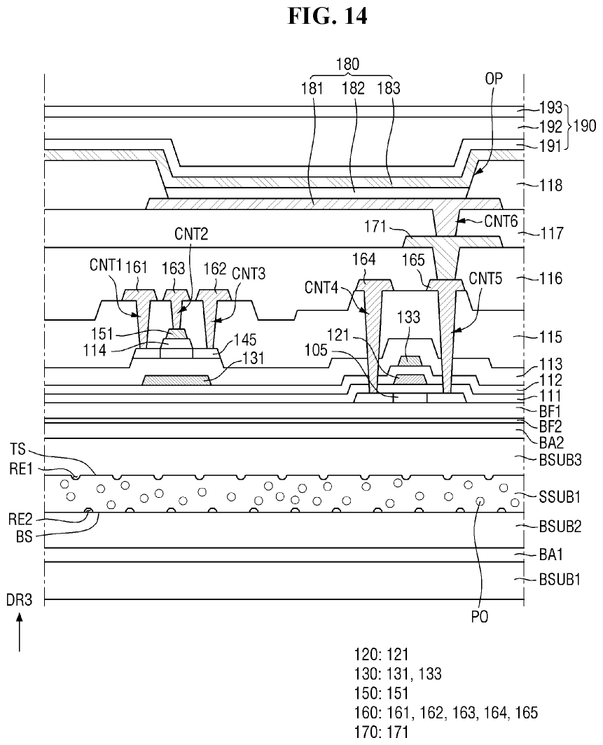

FIG. 13 is a cross-sectional view of another embodiment of a display device constructed according to the principles of the invention. FIG. 14 is a cross-sectional view of yet another embodiment of a display device constructed according to the principles of the invention.

Referring to FIG. 13, the display device 10 may include a first base substrate BSUB1, a first barrier layer BA1 disposed on the first base substrate BSUB1, a second base substrate BSUB2 disposed on the first barrier layer BA1, a first sub-substrate SSUB1 disposed on the second base substrate BSUB2, a third base substrate BSUB3 disposed on the first sub-substrate SSUB1, a second barrier layer BA2 disposed on the third base substrate BSUB3, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 13 is substantially identical to the embodiment of FIG. 9 except that a display device further includes a third base substrate BSUB3, and that a first sub-substrate SSUB1 is disposed between a second base substrate BSUB2 and a third base substrate BSUB3; and, therefore, repetitive descriptions will be omitted to avoid redundancy.

Referring to FIG. 13, a first barrier layer BA1 may be disposed on a first base substrate BSUB1, a second base substrate BSUB2 may be disposed on the first barrier layer BA1, a first sub-substrate SSUB1 may be disposed on the second base substrate BSUB2, and a third base substrate BSUB3 may be disposed on the first sub-substrate SSUB1.

According to this embodiment, the first sub-substrate SSUB1 may have a dielectric constant of about 3 or less. In order to reduce the dielectric constant of the first sub-substrate SSUB1, the first sub-substrate SSUB1 may include a plurality of pores PO. The dielectric constant of the first sub-substrate SSUB1 may be lowered by forming the porosity of the plurality of pores PO included in the first sub-substrate SSUB1 in a range of about 10% to 40%.

As described above, in order to form the pores PO in the first sub-substrate SSUB1, a porogen compound may be mixed and thermally decomposed.

Referring to FIG. 14, when the porogen compound located on the surfaces of the first sub-substrate SSUB1 is thermally decomposed, pores may form where the porogen compound was, and thus a plurality of recesses RE1 and RE2 may be formed on the surfaces.

The first sub-substrate SSUB1 may include a plurality of recesses RE1 and RE2 on the top surface TS and the bottom surface BS, respectively. The plurality of recesses RE1 and RE2 may include first recesses RE1 that are concavely recessed from the top surface TS of the first sub-substrate SSUB1 toward the first base substrate BSUB1. In addition, the plurality of recesses RE1 and RE2 may include second recesses RE2 that are concavely recessed from the bottom surface BS of the first sub-substrate SSUB1 toward the third base substrate BSUB3.

The size of the first recesses RE1 and the second recesses RE2 may be substantially equal to the size of the pores PO included in the first sub-substrate SSUB1. The size of the first recesses RE1 and the second recesses RE2 may range from several nanometers to several tens of micrometers. The first recesses RE1 and the second recesses RE2 may be arranged regularly or irregularly.

The third base substrate BSUB3 may be disposed on the first sub-substrate SSUB1. The third base substrate BSUB3 may be in contact with a surface, i.e., the top surface TS of the first sub-substrate SSUB1, and the plurality of first recesses RE1 may be filled with the third base substrate BSUB3. Specifically, the third base substrate BSUB3 may be used to fill the plurality of first recesses RE1 of the first sub-substrate SSUB1 to provide a flat surface over the first sub-substrate SSUB1, and thus may prevent deterioration of the physical properties of the first sub-substrate SSUB1 as a substrate.

According to an embodiment, the bottom surface of the third base substrate BSUB3 may be disposed closer to the first base substrate BSUB1 than the top surface of the first sub-substrate SSUB1. Also, the top surface of the first sub-substrate SSUB1 may be disposed more distant from the first base substrate BSUB1 than the bottom surface of the third base substrate BSUB3.

According to an embodiment, the first sub-substrate SSUB1 may be disposed on the second base substrate BSUB2. The second base substrate BSUB2 may be in contact with the bottom surface BS of the first sub-substrate SSUB1. The plurality of second recesses RE2 of the first sub-substrate SSUB1 may be spaced apart from the second base substrate BSUB2. The plurality of second recesses RE2 may act as pores between the first sub-substrate SSUB1 and the second base substrate BSUB2. The second base substrate BSUB2 may be disposed under the first sub-substrate SSUB1 to support the first sub-substrate SSUB1, so that it is possible to prevent deterioration of physical properties of the first sub-substrate SSUB1.

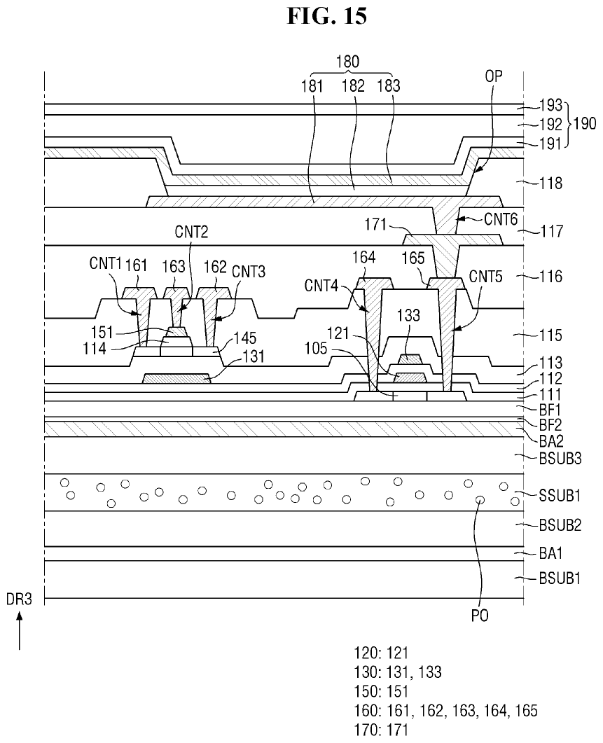

FIG. 15 is a cross-sectional view of still another embodiment of a display device constructed according to the principles of the invention.

Referring to FIG. 15, the display device 10 may include a first base substrate BSUB1, a first barrier layer BA1 disposed on the first base substrate BSUB1, a second base substrate BSUB2 disposed on the first barrier layer BA1, a first sub-substrate SSUB1 disposed on the second base substrate BSUB2, a third base substrate BSUB3 disposed on the first sub-substrate SSUB1, a second barrier layer BA2 disposed on the third base substrate BSUB3, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 15 is substantially identical to the embodiment of FIG. 13 except that a second barrier layer BA2 in contact with a third base substrate BSUB3 has a low dielectric constant; and, therefore, repetitive descriptions will be omitted to avoid redundancy.

Referring to FIG. 15, a third base substrate BSUB3 may be disposed on a first sub-substrate SSUB1 including a plurality of pores PO, and a second barrier layer BA2 may be disposed on the third base substrate BSUB3. The second barrier layer BA2 forms an interface in contact with the third base substrate BSUB3, and electron charging may occur at the interface between the third base substrate BSUB3 and the second barrier layer BA2.

According to this embodiment, the dielectric constant of the second barrier layer BA2 may be lowered to suppress the electron charging. In order to lower the dielectric constant of the second barrier layer BA2, the second barrier layer BA2 may be made of a material having a low dielectric constant or may include a plurality of pores PO. The second barrier layer BA2 may be substantially identical to the second barrier layer BA2 of FIG. 6 described above.

As described above, according to the embodiment of FIG. 15, the second barrier layer BA2 having a low dielectric constant is formed on the third base substrate BSUB3, so that it is possible to reduce the electron charging that occurs on the interface between the third base substrate BSUB3 and the second barrier layer BA2.

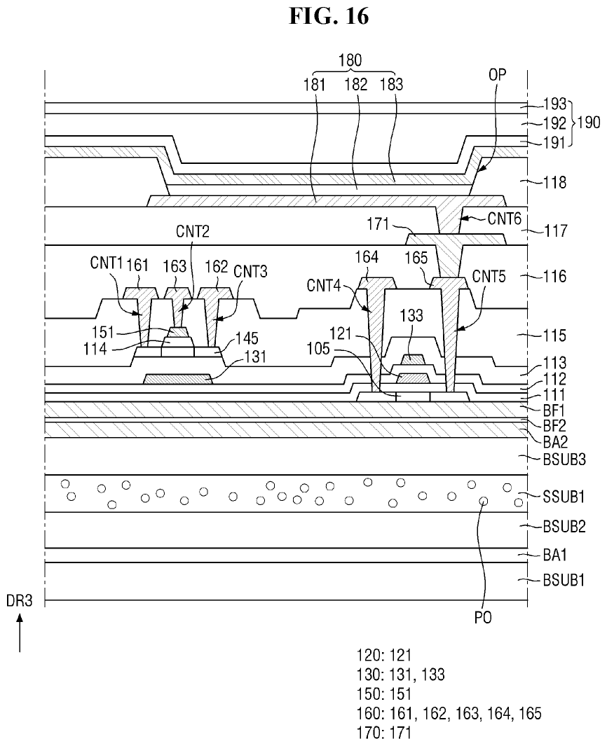

FIG. 16 is a cross-sectional view of yet still another embodiment of a display device constructed according to the principles of the invention.

Referring to FIG. 16, the display device 10 may include a first base substrate BSUB1, a first barrier layer BA1 disposed on the first base substrate BSUB1, a second base substrate BSUB2 disposed on the first barrier layer BA1, a first sub-substrate SSUB1 disposed on the second base substrate BSUB2, a third base substrate BSUB3 disposed on the first sub-substrate SSUB1, a second barrier layer BA2 disposed on the third base substrate BSUB3, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 16 is substantially identical to the embodiment of FIG. 15 except that the first buffer layer BF1 in contact with a polysilicon semiconductor layer 105 has a low dielectric constant; and, therefore, repetitive descriptions will be omitted to avoid redundancy.

Referring to FIG. 16, the first buffer layer BF1 may be disposed under the polysilicon semiconductor layer 105 in contact with it. Since the first buffer layer BF1 is disposed in contact with the polysilicon semiconductor layer 105, if electron charging occurs in the first buffer layer BF1, the characteristics of the thin-film transistors may be greatly affected.

According to an embodiment, the first buffer layer BF1 may be made of a material having a low dielectric constant or may include a plurality of pores PO. The configuration of the first buffer layer BF1 may be substantially identical to the configuration of the above-described second barrier layer BA2 of FIG. 6. Specifically, the first buffer layer BF1 may include a material having a dielectric constant of about 3.5 or less, e.g., a polymer or a silica-based material, and may further include a plurality of pores PO.

Accordingly, the dielectric constant of the first buffer layer BF1 according to the illustrated embodiment of FIG. 16 may be lowered by including a polymer or silica-based material having a low dielectric constant therein or by forming pores therein. By doing so, it is possible to prevent deterioration and/or variation of characteristics of the thin-film transistors by reducing electron charging and interfacial polarization on the first buffer layer BF1.

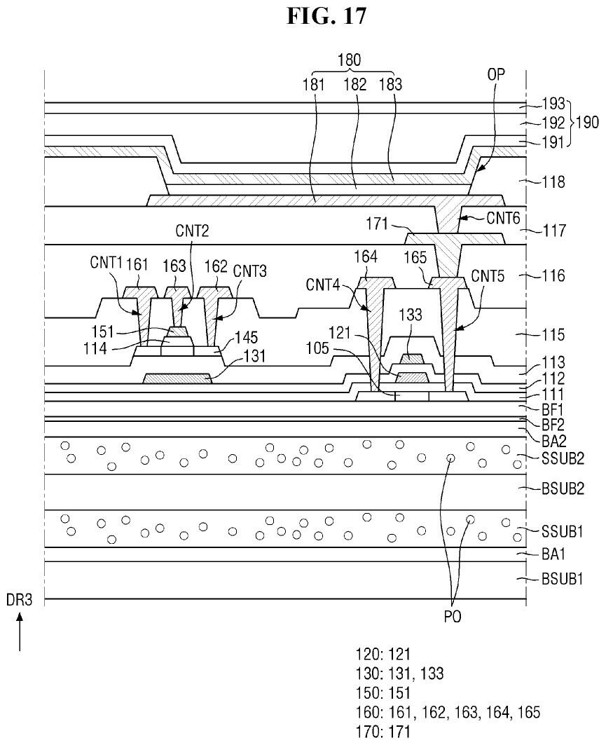

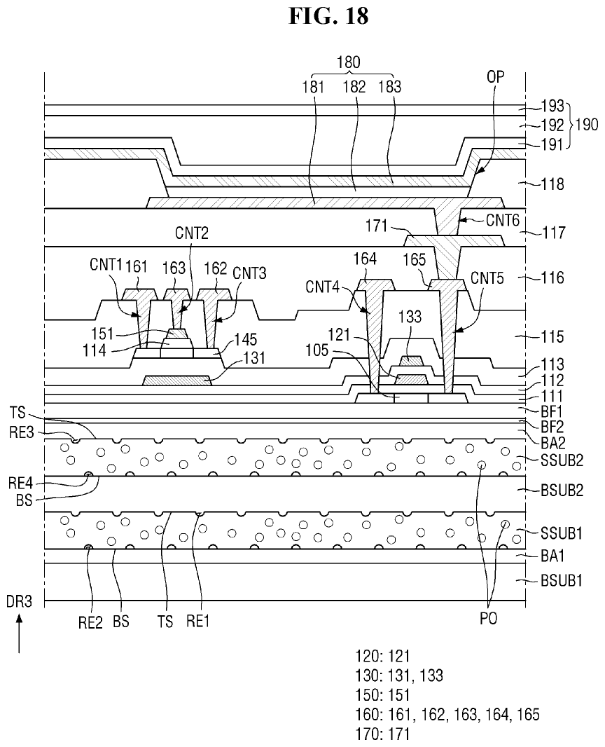

FIG. 17 is a cross-sectional view of another embodiment of a display device constructed according to the principles of the invention. FIG. 18 is a cross-sectional view of still another embodiment of a display device constructed according to the principles of the invention.

Referring to FIG. 17, the display device 10 may include a first base substrate BSUB1, a first barrier layer BA1 disposed on the first base substrate BSUB1, a first sub-substrate SSUB1 disposed on the first barrier layer BA1, a second base substrate BSUB2 disposed on the first sub-substrate SSUB1, a second sub-substrate SSUB2 disposed on the second base substrate BSUB2, a second barrier layer BA2 disposed on the second sub-substrate SSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 17 is substantially identical to the embodiment of FIG. 9 except that a display device further includes a second sub-substrate SSUB2 on a second base substrate BSUB2; and, therefore, repetitive descriptions will be omitted to avoid redundancy.

Referring to FIG. 17, a first barrier layer BA1 may be disposed on a first base substrate BSUB1, a first sub-substrate SSUB1 may be disposed on the first barrier layer BA1, a second base substrate BSUB2 may be disposed on the first sub-substrate SSUB1, a second sub-substrate SSUB2 may be disposed on the second base substrate BSUB2, and a second barrier layer BA2 may be disposed on the second sub-substrate SSUB2.

The display device may further include the second sub-substrate SSUB2 between the second base substrate BSUB2 and the second barrier layer BA2. The second sub-substrate SSUB2 may be an insulating substrate disposed closest to the thin-film transistors described. When a voltage is applied to the gate electrode of the thin-film transistor, ions and/or electrons are charged at the interface between the second sub-substrate SSUB2 and the second barrier layer BA2, and interfacial polarization may occur.

The second sub-substrate SSUB2 according to this embodiment may have substantially the same configuration as the above-described first sub-substrate SSUB1. For example, the second sub-substrate SSUB2 may have a dielectric constant of about 3 or less, and may include a plurality of pores PO. Also, as shown in FIGS. 6, 10 and 14, the second sub-substrate SSUB2 may include a plurality of recesses on the upper surface and the lower surface. That is to say, the second sub-substrate SSUB2 may include all of the characteristics of the first sub-substrate SSUB1 described above.

Accordingly, the second sub-substrate SSUB2 having a dielectric constant of about 3 or less is disposed between the second base substrate BSUB2 and the second barrier layer BA2, so that it is possible to suppress electron charging and interfacial polarization from occurring at the interface between the second barrier layer BA2 and the second sub-substrate SSUB2.

Incidentally, as described above, in order to form the pores PO in the first sub-substrate SSUB1 and the second substrate SSUB3, a porogen compound may be mixed and thermally decomposed.

Referring to FIG. 18, according to another embodiment, when the porogen compound disposed on the surface of each of the first sub-substrate SSUB1 and the second sub-substrate SSUB2 is thermally decomposed, pores may form where the porogen compound was, and thus a plurality of recesses RE1, RE2, RE3 and RE4 may be formed on the surface.

The first sub-substrate SSUB1 may include a plurality of recesses RE1 and RE2 on the top surface TS and the bottom surface BS, respectively. The plurality of recesses RE1 and RE2 may include first recesses RE1 that are concavely recessed from the top surface TS of the first sub-substrate SSUB1 toward the first base substrate BSUB1. In addition, the plurality of recesses RE1 and RE2 may include second recesses RE2 that are concavely recessed from the bottom surface BS of the first sub-substrate SSUB1 toward the second barrier layer BA2.

The size of the first recesses RE1 and the second recesses RE2 may be substantially equal to the size of the pores PO included in the first sub-substrate SSUB1. The size of the first recesses RE1 and the second recesses RE2 may range from several nanometers to several tens of micrometers. The first recesses RE1 and the second recesses RE2 may be arranged regularly or irregularly.

The second base substrate BSUB2 may be disposed on the first sub-substrate SSUB1. The second base substrate BSUB2 may be in contact with a surface, i.e., the top surface TS of the first sub-substrate SSUB1, and the plurality of first recesses RE1 may be filled with the second base substrate BSUB2. Specifically, the second base substrate BSUB2 may be used to fill the plurality of first recesses RE1 of the first sub-substrate SSUB1 to provide a flat surface over the first sub-substrate SSUB1, and thus may prevent deterioration of the physical properties of the first sub-substrate SSUB1 as a substrate.

According to an embodiment, the bottom surface of the second base substrate BSUB2 may be disposed closer to the first base substrate BSUB1 than the top surface of the first sub-substrate SSUB1. Also, the top surface of the first sub-substrate SSUB1 may be disposed more distant from the first base substrate BSUB1 than the bottom surface of the second base substrate BSUB2.

According to an embodiment, the first sub-substrate SSUB1 may be disposed on the first barrier layer BA1. The first barrier layer BA1 may be in contact with the bottom surface BS of the first sub-substrate SSUB1. The plurality of second recesses RE2 of the first sub-substrate SSUB1 may be spaced apart from the first barrier layer BA1. The plurality of second recesses RE2 may act as pores between the first sub-substrate SSUB1 and the first barrier layer BA1. The first barrier layer BA1 may be disposed under the first sub-substrate SSUB1 to support the first sub-substrate SSUB1, so that it is possible to prevent deterioration of physical properties of the first sub-substrate SSUB1.

In addition, the second sub-substrate SSUB2 may include a plurality of recesses RE3 and RE4 on the top surface TS and the bottom surface BS, respectively. The plurality of recesses RE3 and RE4 may include third recesses RE3 that are concavely recessed from the top surface TS of the second sub-substrate SSUB2 toward the first base substrate BSUB1. In addition, the plurality of recesses RE3 and RE4 may include fourth recesses RE4 that are concavely recessed from the bottom surface BS of the second sub-substrate SSUB2 toward the second barrier layer BA2.

The size of the third recesses RE3 and the fourth recesses RE4 may be substantially equal to the size of the pores PO included in the second sub-substrate SSUB2. The size of the third recesses RE3 and the fourth recesses RE4 may range from several nanometers to several tens of micrometers. The third recesses RE3 and the fourth recesses RE4 may be arranged regularly or irregularly.

The second barrier layer BA2 may be disposed on the second sub-substrate SSUB2. The second barrier layer BA2 may be in contact with a surface, i.e., the top surface TS of the second sub-substrate SSUB2, and the plurality of third recesses RE3 may be filled with the second barrier layer BA2. Specifically, the second barrier layer BA2 may be used to fill the plurality of third recesses RE3 of the second sub-substrate SSUB2 to provide a substantially flat surface over the second sub-substrate SSUB2, and thus may prevent or reduce deterioration of the physical properties of the second sub-substrate SSUB2 as a substrate.

According to an embodiment, the bottom surface of the second barrier layer BA2 may be disposed closer to the first base substrate BSUB1 than the top surface of the second sub-substrate SSUB2. Also, the top surface of the second sub-substrate SSUB2 may be disposed more distant from the first base substrate BSUB1 than the bottom surface of the second barrier layer BA2.

According to an embodiment, the second sub-substrate SSUB2 may be disposed on the second base substrate BSUB2. The second base substrate BSUB2 may be in contact with the bottom surface BS of the second sub-substrate SSUB2. The plurality of fourth recesses RE4 of the second sub-substrate SSUB2 may be spaced apart from the second base substrate BSUB2. The plurality of fourth recesses RE4 may act as pores between the second sub-substrate SSUB2 and the second base substrate BSUB2. The second base substrate BSUB2 may be disposed under the second sub-substrate SSUB2 to support the second sub-substrate SSUB2, so that it is possible to prevent deterioration of physical properties of the second sub-substrate SSUB2.

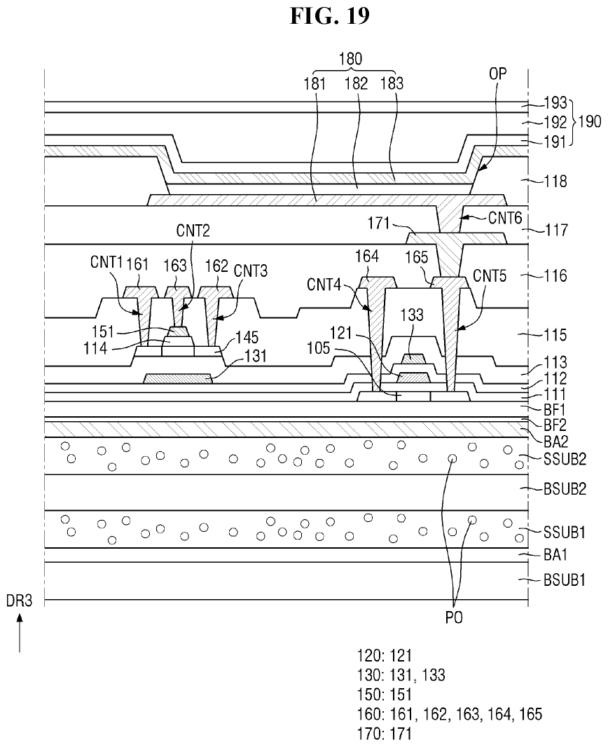

FIG. 19 is a cross-sectional view of yet another embodiment of a display device constructed according to the principles of the invention.

Referring to FIG. 19, the display device 10 may include a first base substrate BSUB1, a first barrier layer BA1 disposed on the first base substrate BSUB1, a first sub-substrate SSUB1 disposed on the first barrier layer BA1, a second base substrate BSUB2 disposed on the first sub-substrate SSUB1, a second sub-substrate SSUB2 disposed on the second base substrate BSUB2, a second barrier layer BA2 disposed on the second sub-substrate SSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 19 is substantially identical to the embodiment of FIG. 17 except that a second barrier layer BA2 in contact with a second sub-substrate SSUB2 has a low dielectric constant; and, therefore, repetitive descriptions will be omitted to avoid redundancy.

Referring to FIG. 19, the second barrier layer BA2 may be disposed on the second sub-substrate SSUB2 including a plurality of pores PO. The second barrier layer BA2 forms an interface in contact with the second sub-substrate SSUB2, and electron charging may occur at the interface between the second sub-substrate SSUB2 and the second barrier layer BA2.

According to this embodiment, the dielectric constant of the second barrier layer BA2 may be lowered to suppress the electron charging. In order to lower the dielectric constant of the second barrier layer BA2, the second barrier layer BA2 may be made of a material having a low dielectric constant or may include a plurality of pores PO. For example, the second barrier layer BA2 may include a polymer or silica-based material having a dielectric constant of about 3.5 or less, and may further include a plurality of pores. The other configuration of the second barrier layer BA2 is substantially identical to that of the second barrier layer BA2 of FIG. 7 described above.

According to this embodiment, the dielectric constant of the second barrier layer BA2 may be lowered by including a polymer or silica-based material having a low dielectric constant in the second barrier layer BA2 or by forming pores therein, in addition to the embodiment of FIG. 17 described above. Accordingly, electron charging at the interface between the second sub-substrate SSUB2 and the second barrier layer BA2 may be suppressed.

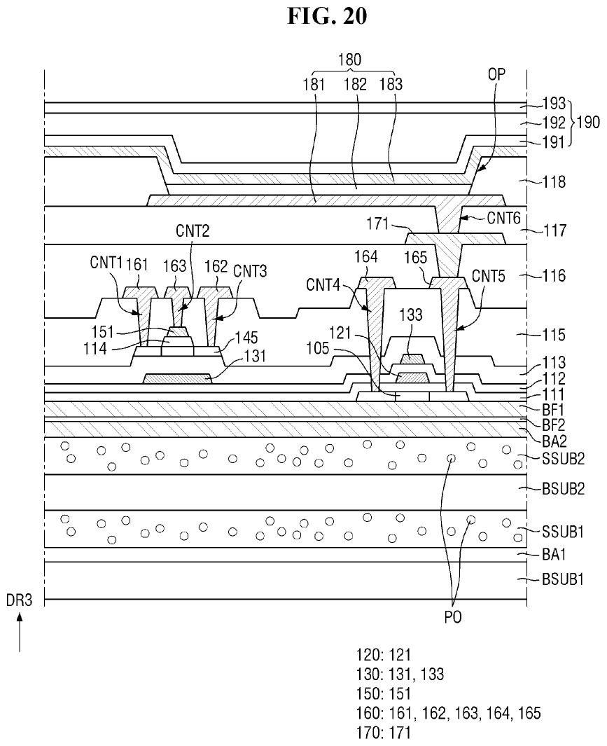

FIG. 20 is a cross-sectional view of still yet another embodiment of a display device constructed according to the principles of the invention.

Referring to FIG. 20, the display device 10 may include a first base substrate BSUB1, a first barrier layer BA1 disposed on the first base substrate BSUB1, a first sub-substrate SSUB1 disposed on the first barrier layer BA1, a second base substrate BSUB2 disposed on the first sub-substrate SSUB1, a second sub-substrate SSUB2 disposed on the second base substrate BSUB2, a second barrier layer BA2 disposed on the second sub-substrate SSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 20 is substantially identical to the embodiment of FIG. 19 except that the first buffer layer BF1 in contact with a polysilicon semiconductor layer 105 has a low dielectric constant; and, therefore, repetitive descriptions will be omitted to avoid redundancy.

Referring to FIG. 20, the first buffer layer BF1 may be disposed under the polysilicon semiconductor layer 105 in contact with it. Since the first buffer layer BF1 is disposed in contact with the polysilicon semiconductor layer 105, if electron charging or interfacial polarization occurs in the first buffer layer BF1, the characteristics of the thin-film transistors may be greatly affected.

According to an embodiment, the first buffer layer BF1 may be made of a material having a low dielectric constant or may include a plurality of pores PO. The configuration of the first buffer layer BF1 may be substantially identical to the configuration of the above-described second barrier layer BA2 of FIG. 6. Specifically, the first buffer layer BF1 may include a material having a dielectric constant of about 3.5 or less, e.g., a polymer or a silica-based material, and may further include a plurality of pores PO.

Accordingly, the dielectric constant of the first buffer layer BF1 according to the illustrated embodiment of FIG. 20 may be lowered by including a polymer or silica-based material having a low dielectric constant therein or by forming pores therein. By doing so, it is possible to prevent deterioration in and/or variation of electrical characteristics of the thin-film transistors by suppressing electron charging and interfacial polarization on the first buffer layer BF1.

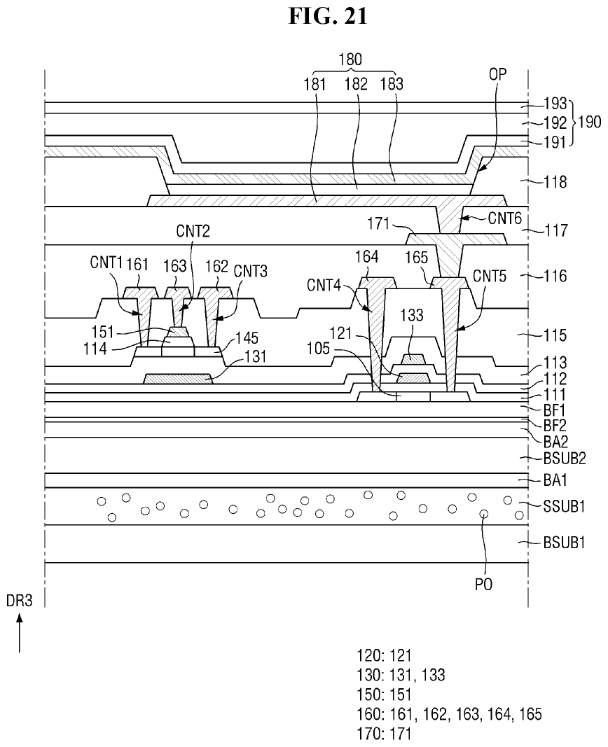

FIGS. 21 to 31 are cross-sectional views of other embodiments of display devices constructed according to the principles of the invention.

Referring to FIG. 21, the display device 10 may include a first base substrate BSUB1, a first sub-substrate SSUB1 disposed on the first base substrate BSUB1, a first barrier layer BA1 disposed on the first sub-substrate SSUB1, a second base substrate BSUB2 disposed on the first barrier layer BA1, a second barrier layer BA2 disposed on the second base substrate BSUB2, a second buffer layer BF2 disposed on the second barrier layer BA2, a first buffer layer BF1 disposed on the second buffer layer BF2, a switching transistor disposed on the first buffer layer BF1, a driving transistor, and an organic light-emitting diode 180.

The embodiment of FIG. 21 is different from the above-described embodiment of FIG. 4 in that the first sub-substrate SSUB1 is disposed between the first base substrate BSUB1 and the first barrier layer BA1. According to an embodiment, it is possible to suppress interfacial polarization at the interface with the first barrier layer BA1 by lowering the dielectric constant of the first sub-substrate SSUB1.

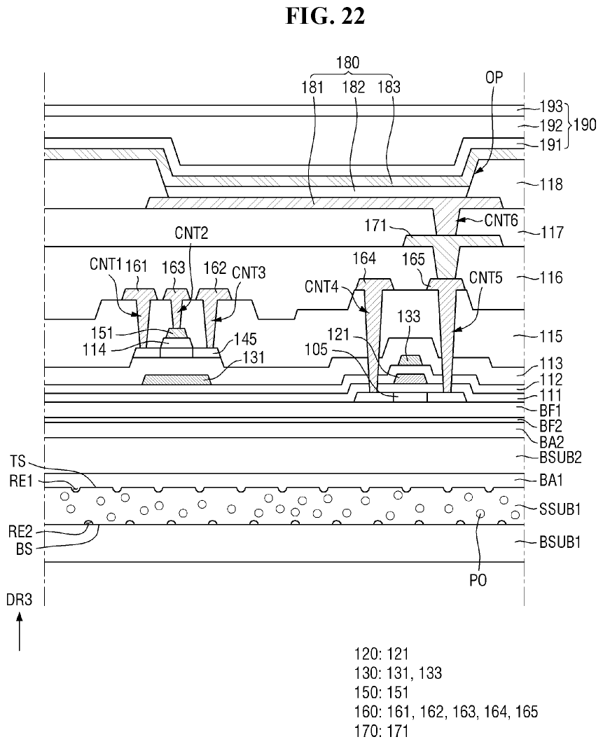

The embodiment of FIG. 22 is different from the above-described embodiment of FIG. 6 in that a first sub-substrate SSUB1 is disposed between a first base substrate BSUB1 and a first barrier layer BA1. According to an embodiment, it is possible to prevent deterioration of physical properties of the first sub-substrate SSUB1 since the first sub-substrate SSUB1 is covered and/or supported by the first barrier layer BA1 and the first base substrate BSUB1 while including the plurality of recesses RE1 and RE2.

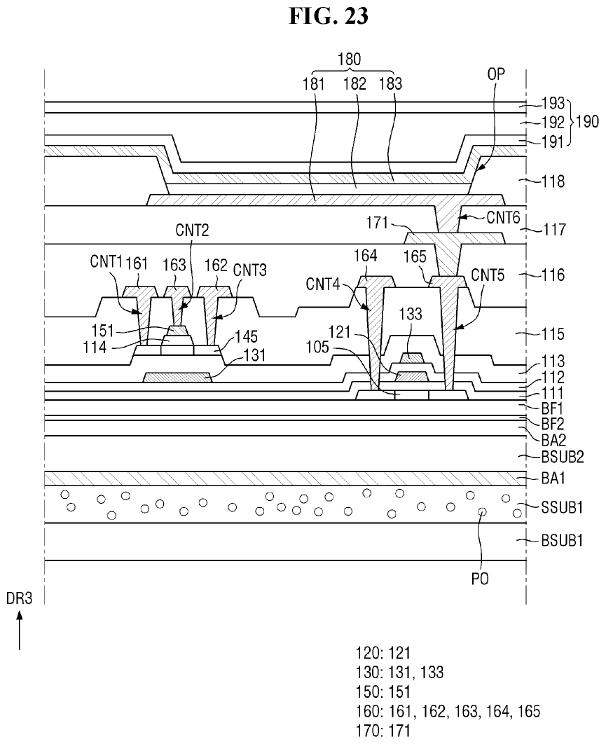

The embodiment of FIG. 23 is different from the above-described embodiment of FIG. 7 in that a first sub-substrate SSUB1 is disposed between a first base substrate BSUB1 and a first barrier layer BA1, and that a first barrier layer BA1 has a low dielectric constant. According to an embodiment, it is possible to suppress electron charging at the interface between the first sub-substrate SSUB1 and the first barrier layer BA1 by lowering the dielectric constant of the first barrier layer BA1.

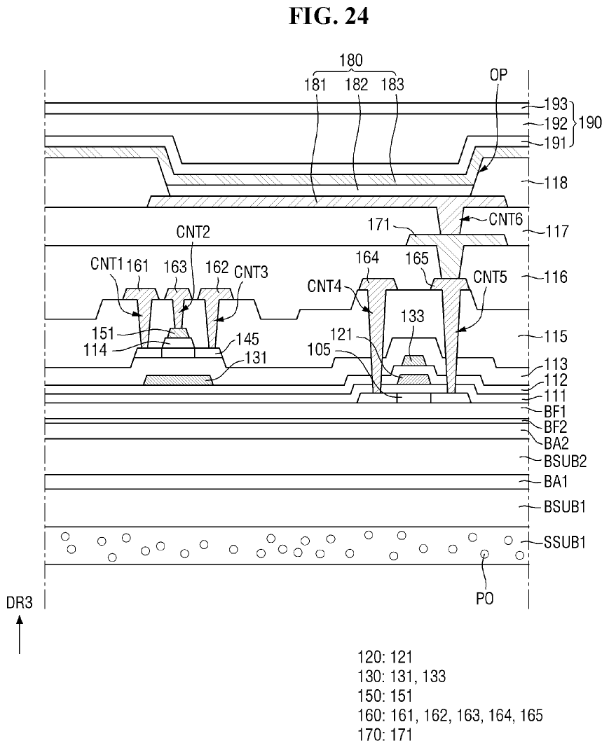

The embodiment of FIG. 24 is different from the above-described embodiment of FIG. 9 in that a first sub-substrate SSUB1 is disposed under a first base substrate BSUB1. According to an embodiment, the dielectric constant of the first sub-substrate SSUB1 may be lowered as the first sub-substrate SSUB1 includes the plurality of pores PO.

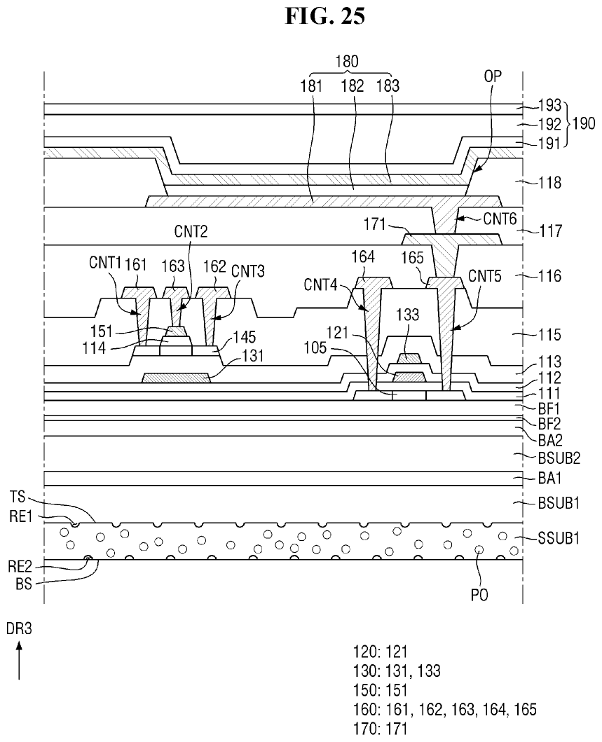

The embodiment of FIG. 25 is different from the above-described embodiment of FIG. 10 in that a first sub-substrate SSUB1 is disposed under a first base substrate BSUB1. According to an embodiment, it is possible to prevent deterioration of physical properties of the first sub-substrate SSUB1 since the first sub-substrate SSUB1 is covered by the first base substrate BSUB1 while including the plurality of recesses RE1 and RE2.

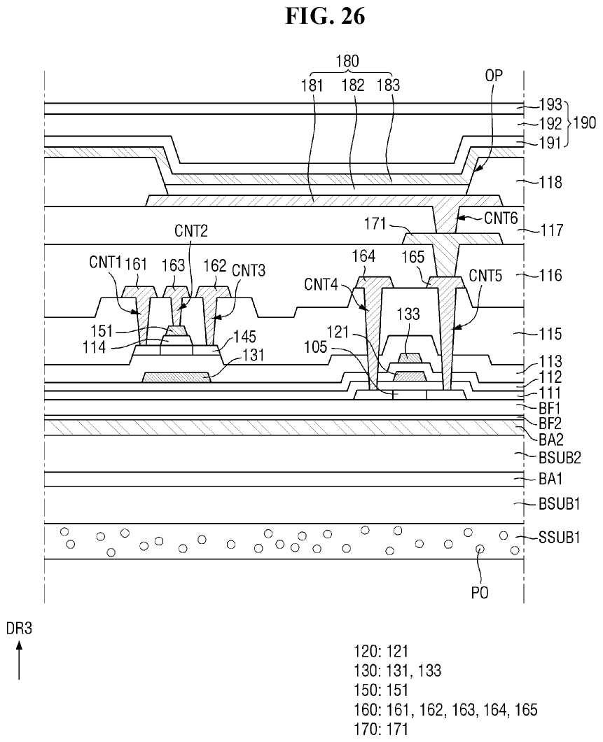

The embodiment of FIG. 26 is different from the above-described embodiment of FIG. 11 in that a first sub-substrate SSUB1 is disposed under a first base substrate BSUB1. According to an embodiment, the second barrier layer BA2 having a low dielectric constant is formed on the second base substrate BSUB2, so that it is possible to reduce the electron charging that occurs at the interface between the second base substrate BSUB2 and the second barrier layer BA2.

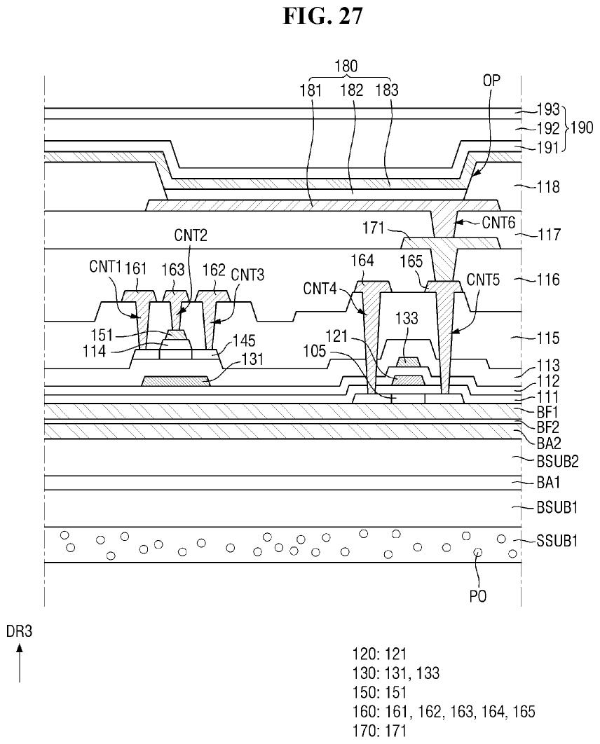

The embodiment of FIG. 27 is different from the above-described embodiment of FIG. 12 in that a first sub-substrate SSUB1 is disposed under a first base substrate BSUB1. According to an embodiment, it is possible to prevent deterioration and/or variation of characteristics of the thin-film transistors by suppressing electron charging on the first buffer layer BF1.

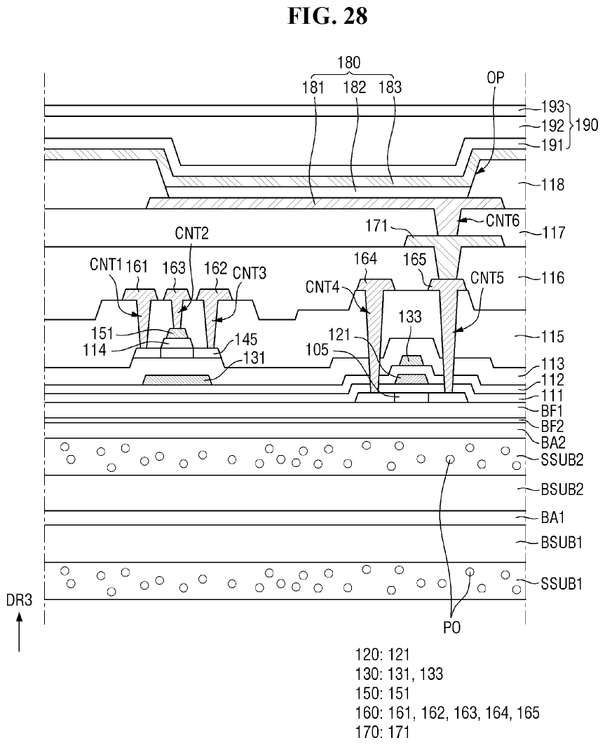

The embodiment of FIG. 28 is different from the above-described embodiment of FIG. 17 in that a first sub-substrate SSUB1 is disposed under a first base substrate BSUB1. According to an embodiment, the second sub-substrate SSUB2 having a dielectric constant of about 3 or less is disposed between the second base substrate BSUB2 and the second barrier layer BA2, so that it is possible to suppress electron charging and interfacial polarization from occurring at the interface between the second barrier layer BA2 and the second sub-substrate SSUB2.

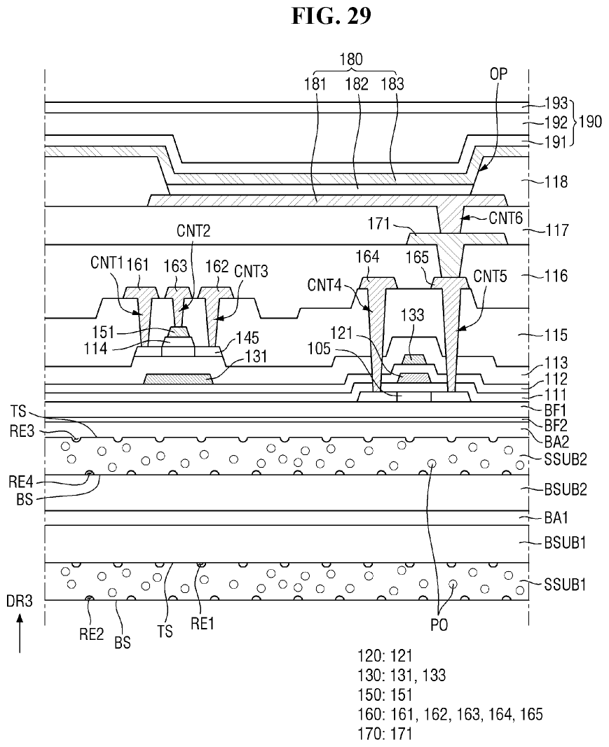

The embodiment of FIG. 29 is different from the above-described embodiment of FIG. 18 in that a first sub-substrate SSUB1 is disposed under a first base substrate BSUB1. According to an embodiment, it is possible to prevent deterioration of physical properties of a first sub-substrate SSUB1 and a second sub-substrate SSUB2 since the first sub-substrate SSUB1 is covered by the first base substrate BSUB1 and the second sub-substrate SSB2 is covered and/or supported by the second barrier layer BA2 and the second base substrate BSUB2 while the first and second sub-substrates SSUB1 and SSUB2 include the plurality of recesses RE1 to RE4.

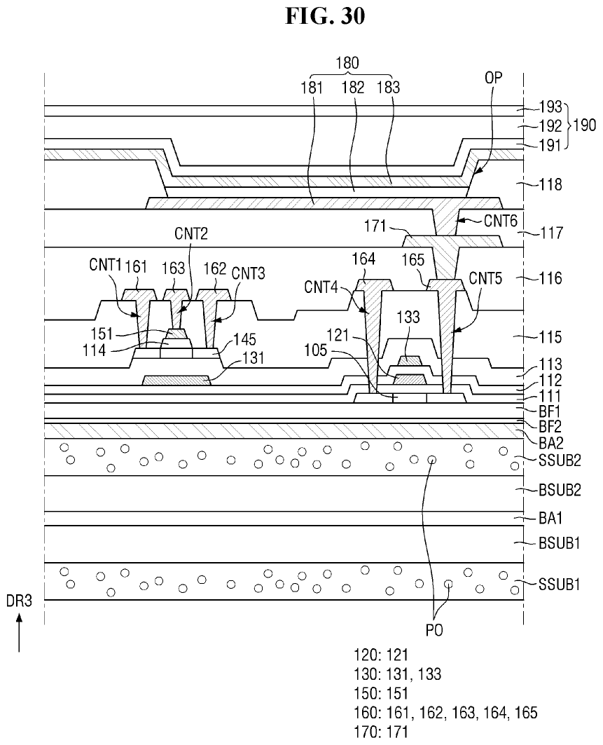

The embodiment of FIG. 30 is different from the above-described embodiment of FIG. 19 in that a first sub-substrate SSUB1 is disposed under a first base substrate BSUB1. According to an embodiment, it is possible to suppress electron charging at the interface between the second sub-substrate SSUB2 and the second barrier layer BA2 by lowering the dielectric constant of the second barrier layer BA2.

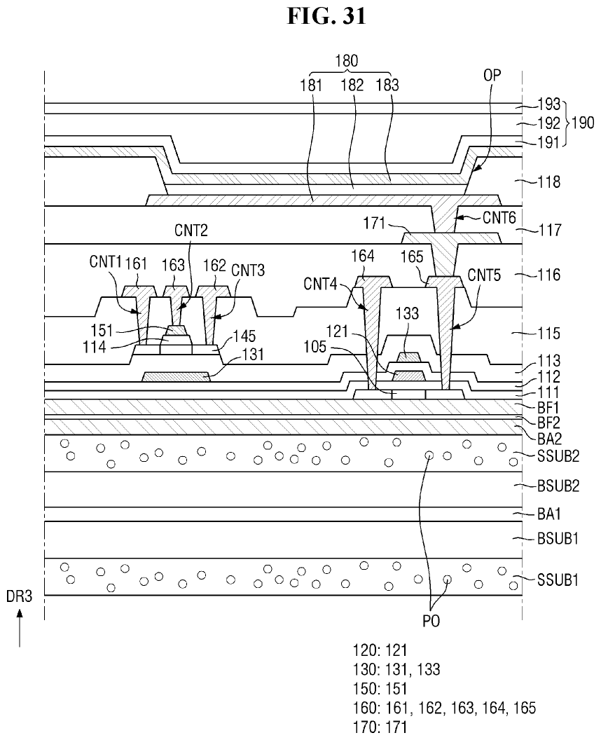

The embodiment of FIG. 31 is different from the above-described embodiment of FIG. 20 in that a first sub-substrate SSUB1 is disposed under a first base substrate BSUB1. According to an embodiment, it is possible to prevent deterioration in and/or variation of characteristics of the thin-film transistors by suppressing electron charging on the first buffer layer BF1.

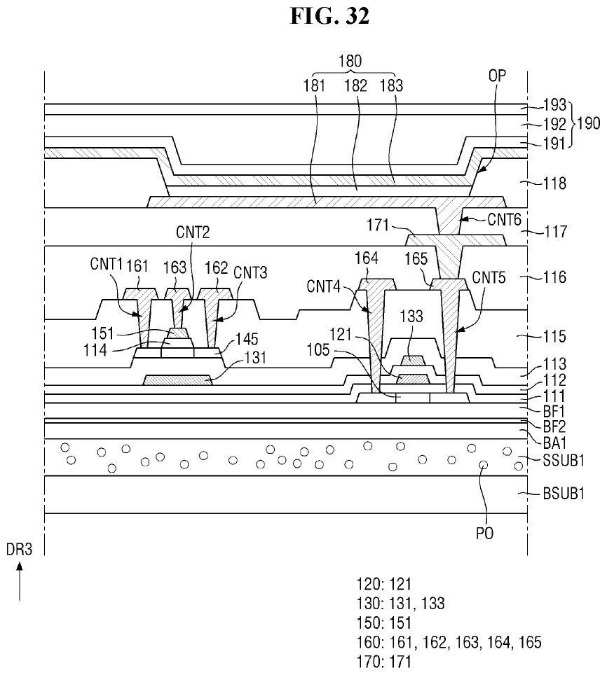

FIGS. 32 to 47 are cross-sectional views of still other embodiments of display devices constructed according to the principles of the invention.

Referring to FIG. 32, the display device 10 may include a first base substrate BSUB1, a first sub-substrate SSUB1 disposed on the first base substrate BSUB1, a first barrier layer BA1 disposed on the first sub-substrate SSUB1, a second barrier layer BA2 disposed on the first barrier layer BA1, a first buffer layer BF1 disposed on the second buffer layer BF2, a switching transistor disposed on the first buffer layer BF1, a driving transistor, and an organic light-emitting diode 180.

The embodiment of FIG. 32 is different from the above-described embodiment of FIG. 4 in that a first barrier layer BA1 and a second base substrate BSUB2 are eliminated, and that the second barrier layer BA2 is referred to as the first barrier layer BA1. According to an embodiment, it is possible to suppress interfacial polarization at the interface with the first barrier layer BA1 by lowering the dielectric constant of the first sub-substrate SSUB1.

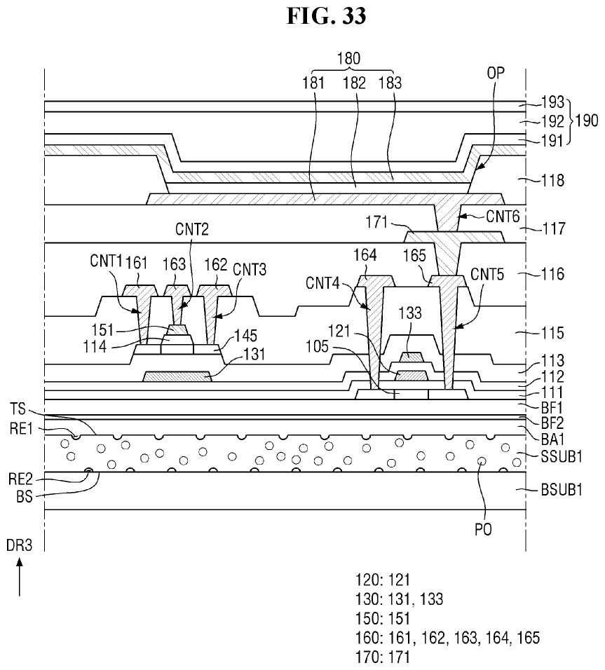

The embodiment of FIG. 33 is different from the above-described embodiment of FIG. 6 in that a first barrier layer BA1 and a second base substrate BSUB2 are eliminated, and that the second barrier layer BA2 is referred to as the first barrier layer BA1. According to an embodiment, it is possible to prevent deterioration of physical properties of the first sub-substrate SSUB1 since the first sub-substrate SSUB1 is covered and/or supported by the first barrier layer BA1 and the first base substrate BSUB1 while including the plurality of recesses RE1 and RE2.

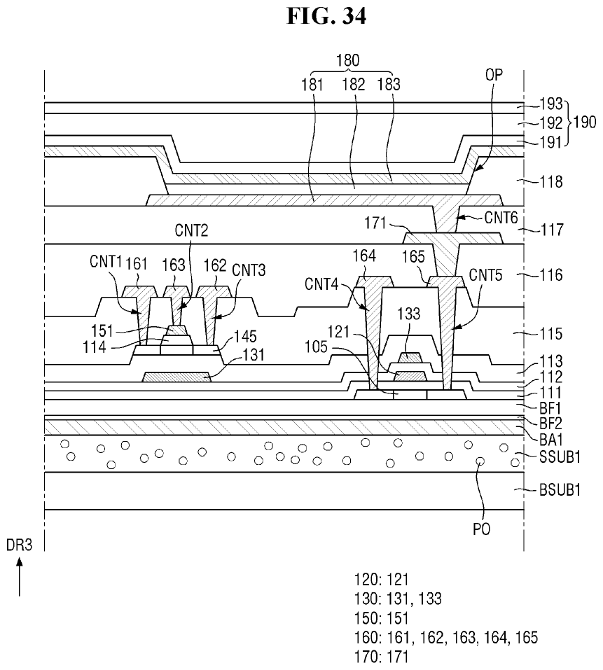

The embodiment of FIG. 34 is different from the above-described embodiment of FIG. 7 in that a first barrier layer BA1 and a second base substrate BSUB2 are eliminated, and that the second barrier layer BA2 is referred to as the first barrier layer BA1. According to an embodiment, it is possible to suppress electron charging at the interface between the first sub-substrate SSUB1 and the first barrier layer BA1 by lowering the dielectric constant of the first barrier layer BA1.

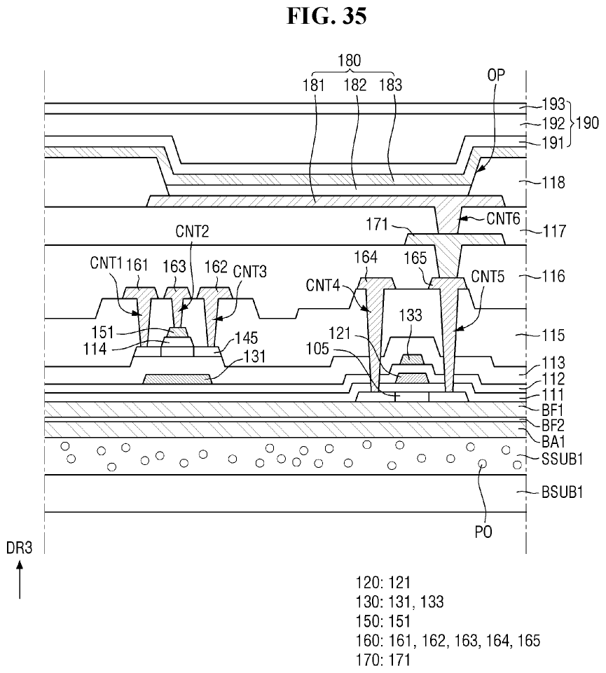

The embodiment of FIG. 35 is different from the above-described embodiment of FIG. 8 in that a first barrier layer BA1 and a second base substrate BSUB2 are eliminated, and that the second barrier layer BA2 is referred to as the first barrier layer BA1. According to an embodiment, it is possible to prevent deterioration and/or variation of characteristics of the thin-film transistors by suppressing electron charging and interfacial polarization on the first buffer layer BF1.

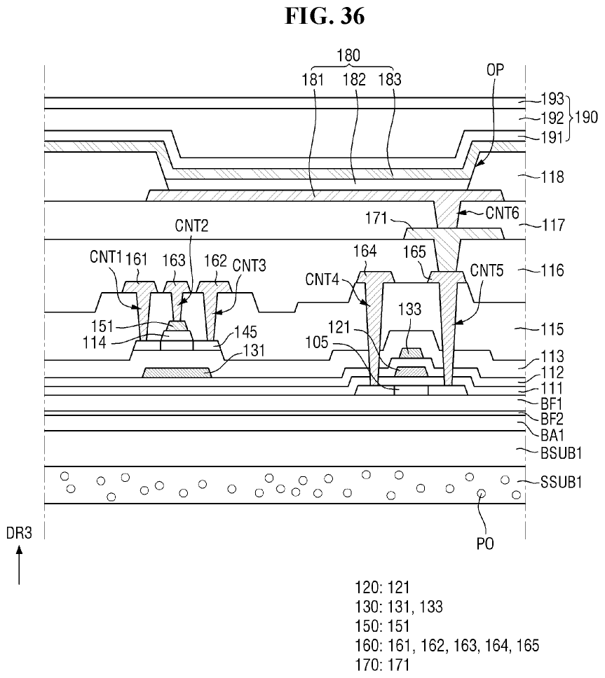

The embodiment of FIG. 36 is different from the above-described embodiment of FIG. 9 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, the dielectric constant of the first sub-substrate SSUB1 may be lowered as the first sub-substrate SSUB1 includes the plurality of pores PO.

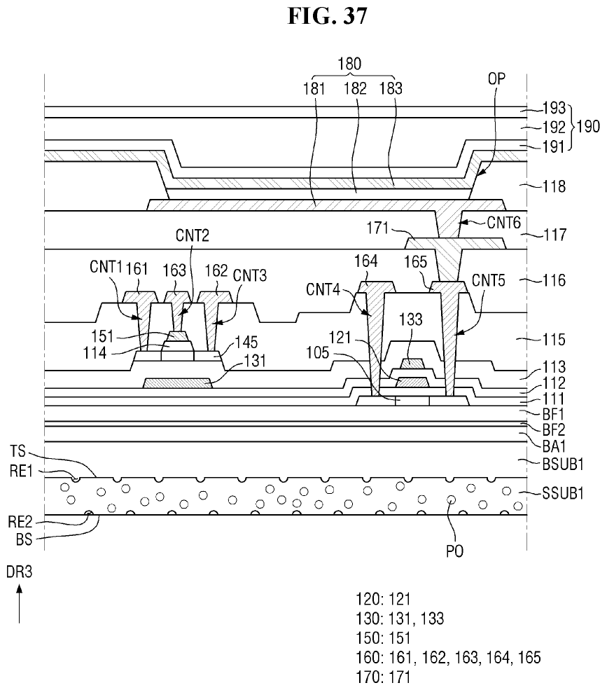

The embodiment of FIG. 37 is different from the above-described embodiment of FIG. 10 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, it is possible to prevent deterioration of physical properties of the first sub-substrate SSUB1 since the first sub-substrate SSUB1 is covered by the first base substrate BSUB1 while including the plurality of recesses RE1 and RE2.

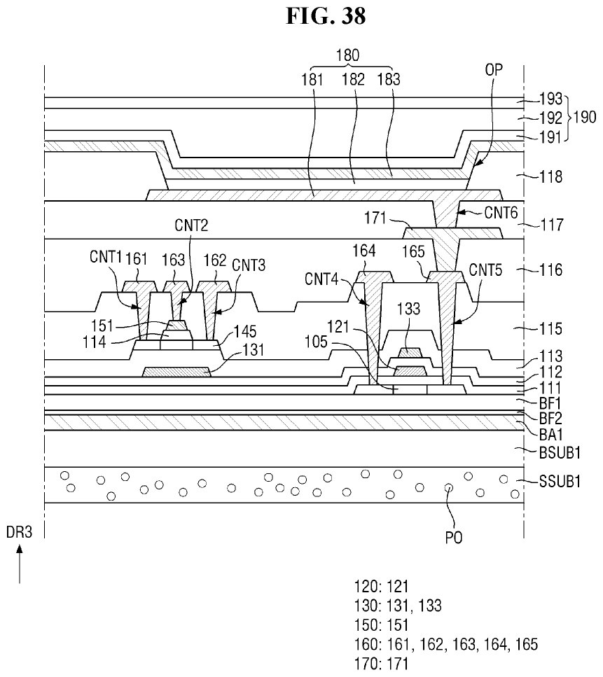

The embodiment of FIG. 38 is different from the above-described embodiment of FIG. 11 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, the second barrier layer BA2 having a low dielectric constant is formed on the first base substrate BSUB1, so that it is possible to suppress the electron charging that occurs at the interface between the first base substrate BSUB1 and the first barrier layer BA1.

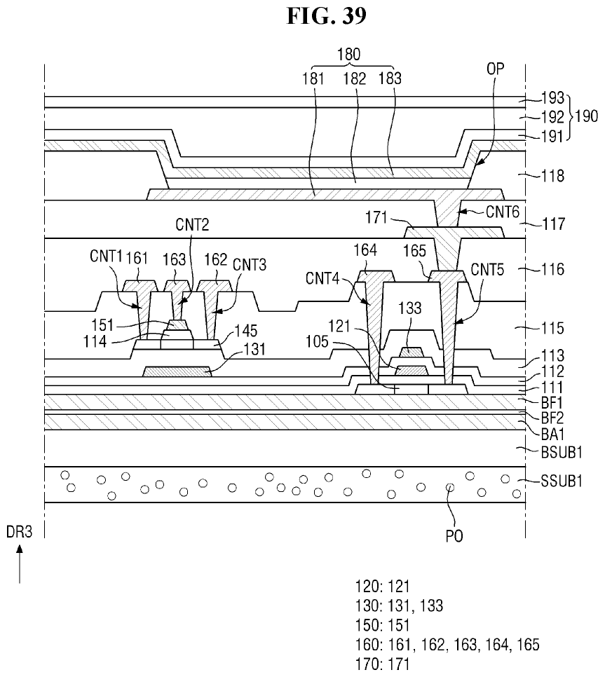

The embodiment of FIG. 39 is different from the above-described embodiment of FIG. 12 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, it is possible to prevent deterioration and/or variation of characteristics of the thin-film transistors by suppressing electron charging on the first buffer layer BF1.

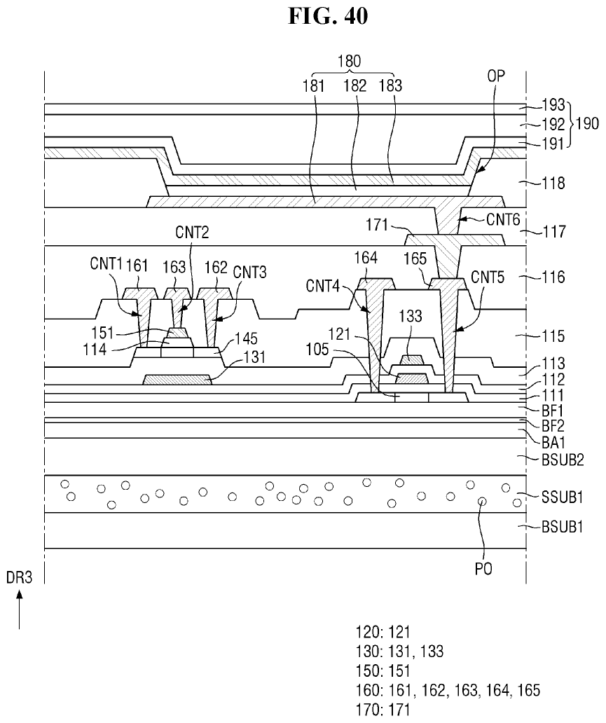

The embodiment of FIG. 40 is different from the above-described embodiment of FIG. 13 in that a first barrier layer BA1 and a first base substrate BSUB1 are eliminated, that the second barrier layer BA2 is referred to as the first barrier layer BA1, that the second base substrate BSUB2 is referred to as the first base substrate BSUB1, and that the third base substrate BSUB3 is referred to as the second base substrate BSUB2. According to an embodiment, the dielectric constant of the first sub-substrate SSUB1 may be lowered as the first sub-substrate SSUB1 includes the plurality of pores PO.

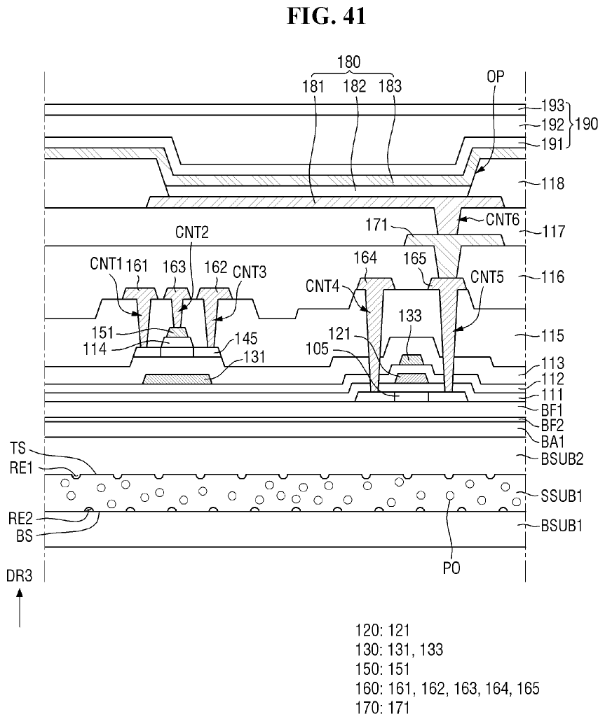

The embodiment of FIG. 41 is different from the above-described embodiment of FIG. 14 in that a first barrier layer BA1 and a first base substrate BSUB1 are eliminated, that the second barrier layer BA2 is referred to as the first barrier layer BA1, that the second base substrate BSUB2 is referred to as the first base substrate BSUB1, and that the third base substrate BSUB3 is referred to as the second base substrate BSUB2. According to an embodiment, it is possible to prevent deterioration of physical properties of the first sub-substrate SSUB1 since the first sub-substrate SSUB1 is covered and/or supported by the first and second base substrates BSUB1 and BSUB2 while including the plurality of recesses RE1 and RE2.

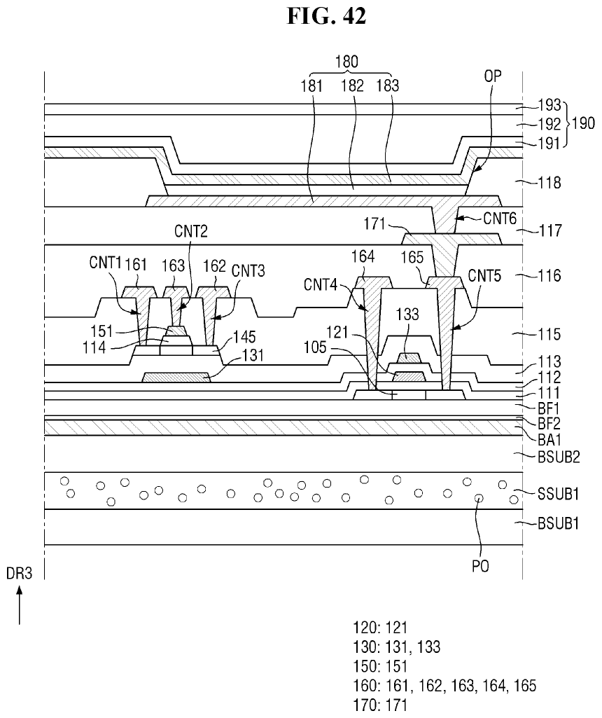

The embodiment of FIG. 42 is different from the above-described embodiment of FIG. 15 in that a first barrier layer BA1 and a first base substrate BSUB1 are eliminated, that the second barrier layer BA2 is referred to as the first barrier layer BA1, that the second base substrate BSUB2 is referred to as the first base substrate BSUB1, and that the third base substrate BSUB3 is referred to as the second base substrate BSUB2. According to an embodiment, the first barrier layer BA1 having a low dielectric constant is formed on the second base substrate BSUB2, so that it is possible to suppress the electron charging that occurs at the interface between the second base substrate BSUB2 and the first barrier layer BA1.

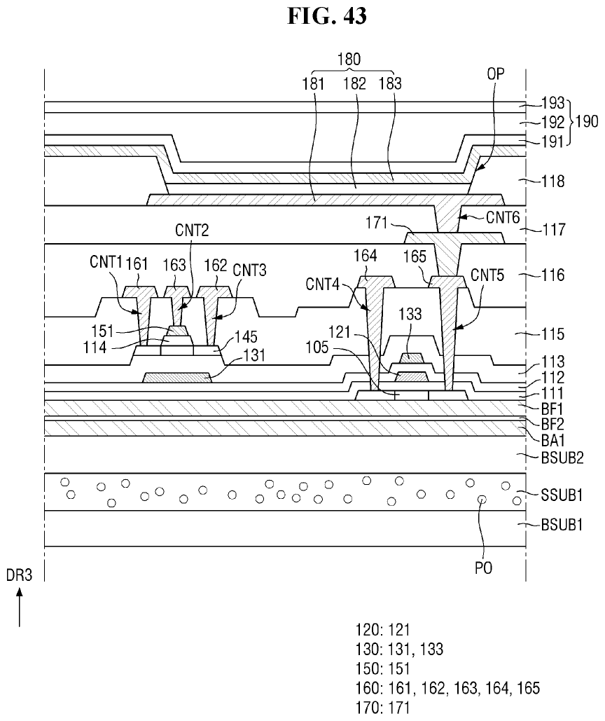

The embodiment of FIG. 43 is different from the above-described embodiment of FIG. 16 in that a first barrier layer BA1 and a first base substrate BSUB1 are eliminated, that the second barrier layer BA2 is referred to as the first barrier layer BA1, that the second base substrate BSUB2 is referred to as the first base substrate BSUB1, and that the third base substrate BSUB3 is referred to as the second base substrate BSUB2. According to an embodiment, it is possible to prevent deterioration in and/or variation of characteristics of the thin-film transistors by suppressing electron charging on the first buffer layer BF1.

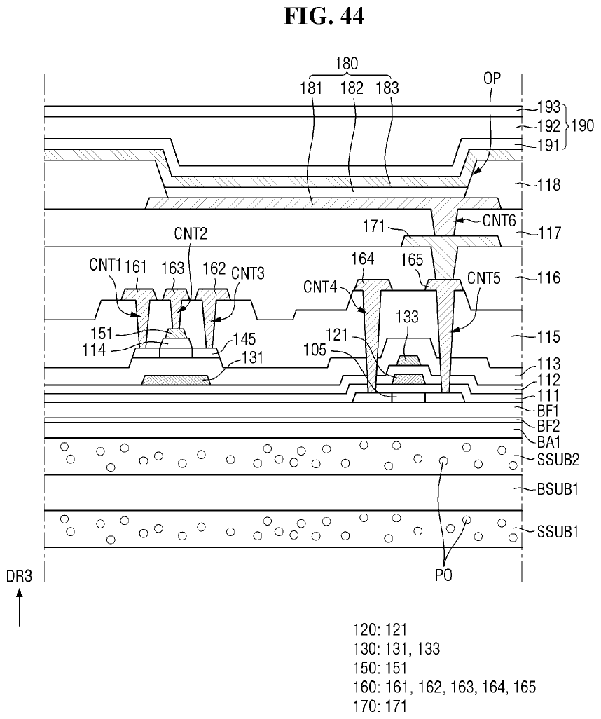

The embodiment of FIG. 44 is different from the above-described embodiment of FIG. 17 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, the second sub-substrate SSUB2 having a dielectric constant of about 3 or less is disposed between the first base substrate BSUB1 and the first barrier layer BA1, so that it is possible to suppress electron charging and interfacial polarization from occurring at the interface between the first barrier layer BA1 and the second sub-substrate SSUB2.

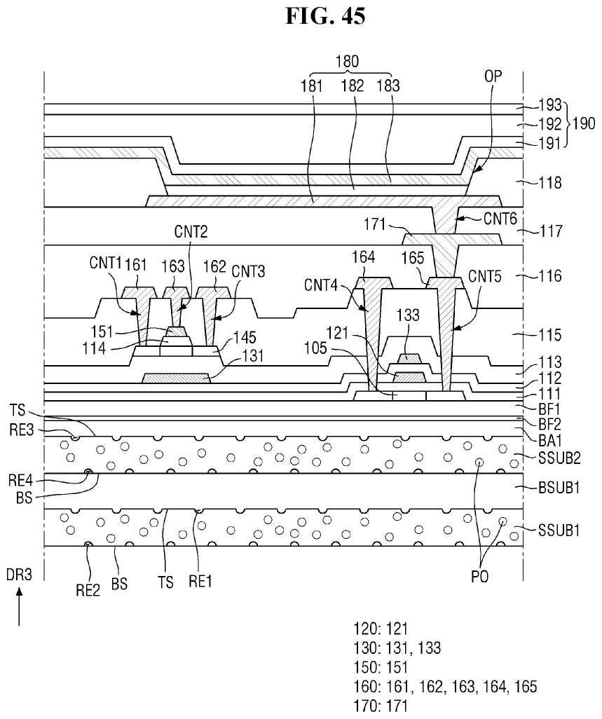

The embodiment of FIG. 45 is different from the above-described embodiment of FIG. 18 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, it is possible to prevent deterioration of physical properties of a first sub-substrate SSUB1 and a second sub-substrate SSUB2 since the first sub-substrate SSUB1 is covered by the first base substrate BSUB1 and the second sub-substrate SSB2 is covered and/or supported by the first barrier layer BA1 and the first base substrate BSUB1 while the first and second sub-substrates SSUB1 and SSUB2 include the plurality of recesses RE1 to RE4.

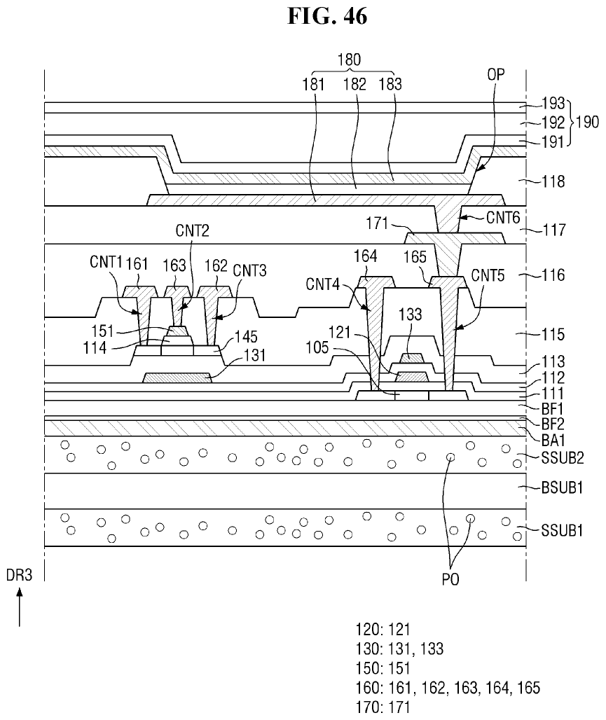

The embodiment of FIG. 46 is different from the above-described embodiment of FIG. 19 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, it is possible to suppress electron charging at the interface between the second sub-substrate SSUB2 and the first barrier layer BA1 by lowering the dielectric constant of the first barrier layer BA1.

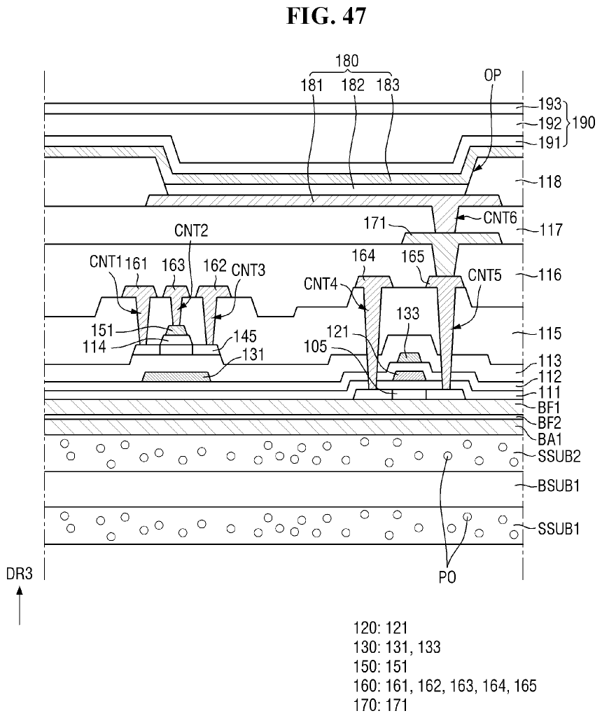

The embodiment of FIG. 47 is different from the above-described embodiment of FIG. 20 in that a first barrier layer BA1 and a first base substrate BSUB1 are eliminated, that the second barrier layer BA2 is referred to as the first barrier layer BA1, and that the second base substrate BSUB2 is referred to as the first base substrate BSUB1. According to an embodiment, it is possible to prevent deterioration in and/or variation of characteristics of the thin-film transistors by suppressing electron charging on the first buffer layer BF1.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a first substrate;
a second substrate disposed on the first substrate and comprising a plurality of voids;
at least one inorganic layer disposed on the second substrate;
at least one transistor disposed on the at least one inorganic layer; and
a light-emitter disposed on the at least one transistor,
wherein the second substrate is in contact with the at least one inorganic layer and has a dielectric constant less than a dielectric constant of the at least one inorganic layer.

2. The display device of claim 1, wherein the voids in the second substrate comprise pores having a porosity in the range of about 10% to about 40%.

3. The display device of claim 1, wherein the second substrate has a dielectric constant of about 2 to about 3, and the at least one inorganic layer has a dielectric constant of about 3.5 or less.

4. The display device of claim 1, wherein the first substrate comprises at least one non-porous base substrate, and the second substrate comprises at least one porous sub-substrate including the plurality of voids.

5. The display device of claim 3, wherein the at least one inorganic layer comprises a polymer resin or a silica-based material, and
wherein the silica-based material comprises one selected from the group consisting of: porous silica, HSQ, OSG, and FSG; and the polymer resin comprises one selected from the group consisting of: PTFE, BPDA-PDA, PAE, SiLK, BCB, Parylene-N, and Parylene-F.

6. The display device of claim 3, wherein the at least one inorganic layer comprises a plurality of voids.

7. The display device of claim 3, wherein the at least one inorganic layer comprises at least one of fluorine, boron, phosphorus, arsenic and argon.

8. The display device of claim 1, wherein the first substrate comprises a first base substrate and a second base substrate disposed on the first base substrate, and
wherein the second substrate is disposed on the second base substrate.

9. The display device of claim 8, further comprising:
a third substrate disposed between the first base substrate and the second base substrate,
wherein the third substrate comprises a plurality of voids.

10. The display device of claim 9, wherein each of the first base substrate, the second base substrate, the second substrate and the third substrate comprises a polyimide resin.

11. The display device of claim 1, wherein the at least one inorganic layer comprises at least one barrier layer and at least one buffer layer disposed on the at least one barrier layer.

12. The display device of claim 1, wherein the second substrate comprises a plurality of recesses formed on at least one surface.

13. The display device of claim 1, wherein the light-emitter comprises an organic light-emitting diode.

14. A display device comprising:
a plurality of base substrates;
a first sub-substrate disposed on the plurality of base substrates and comprising a plurality of voids;
at least one inorganic layer disposed on the base substrates;
at least one transistor disposed on the at least one inorganic layer; and
a light-emitter disposed on the at least one transistor,
wherein the first sub-substrate is in contact with the at least one inorganic layer and has a dielectric constant less than a dielectric constant of the at least one inorganic layer.

15. The display device of claim 14, the voids in the first sub-substrate comprise pores having a porosity ranging from about 10% to about 40%.

16. The display device of claim 14, wherein the first sub-substrate has a dielectric constant of about 2 to about 3, and the at least one inorganic layer has a dielectric constant of about 3.5 or less.

17. The display device of claim 16, wherein the at least one inorganic layer comprises a polymer resin or a silica-based material, and
wherein the silica-based material comprises one selected from the group consisting of: porous silica, HSQ, OSG and FSG; and the polymer resin comprises one selected from the group consisting of: PTFE, BPDA-PDA, PAE, SiLK, BCB, Parylene-N, and Parylene-F.

18. The display device of claim 16, wherein the at least one inorganic layer comprises a plurality of voids.

19. The display device of claim 16, wherein the at least one inorganic layer includes at least one of fluorine, boron, phosphorus, arsenic and argon.

20. The display device of claim 14, wherein the plurality of base substrates comprises a first base substrate and a second base substrate disposed on the first base substrate, and wherein the first sub-substrate is disposed between the first base substrate and the second base substrate.

21. The display device of claim 20, further comprising:
a second sub-substrate disposed on the second base substrate,
wherein the second sub-substrate comprises a plurality of voids.

22. The display device of claim 14, wherein the light-emitter comprises an organic light-emitting diode.
